(19) United States
(12) Patent Application Publication
(10) Pub. No.: US 2026/0033322 A1
(43) Pub. Date: Jan. 29, 2026

(54) CAPACITOR STRUCTURES AND METHODS OF FORMATION

(71) Applicant: Taiwan Semiconductor Manufacturing Company, Ltd., Hsinchu (TW)

(72) Inventors: Kuo-Cheng LEE, Tainan City (TW); Chia-Yu WEI, Tainan City (TW); Chun-Lin FANG, Tainan City (TW); Bo-Ge HUANG, Tainan City (TW); Ming-Hong SU, Tainan (TW)

(21) Appl. No.: 18/784,562

(22) Filed: Jul. 25, 2024

(51) Int. Cl. H01L 23/522; H01L 27/146

(52) U.S. Cl. CPC H01L 23/5223; H10F 39/809; H10F 39/811

(57) ABSTRACT

An image sensor device includes a capacitor structure that is configured to store charge associated with a photocurrent that is generated by a pixel sensor in a pixel sensor array of the image sensor device. The capacitor structure may include bottom electrode layers and top electrode layers that are arranged in an alternating manner and separated by insulator layers. The ends of the bottom electrode layers facing a top contact structure are etched such that the ends of the bottom electrode layers are spaced apart from the top contact structure. Similarly, the ends of the top electrode layers facing a bottom contact structure are etched such that the ends of the top electrode layers are spaced apart from the bottom contact structure.

### BACKGROUND

A complementary metal oxide semiconductor (CMOS) image sensor may include a plurality of pixel sensors arranged in a pixel sensor array. A pixel sensor of the CMOS image sensor may include a photodiode configured to convert photons of incident light to a photocurrent of electrons. The magnitude of the photocurrent is based at least in part on the intensity of the incident light. Accordingly, if the pixel sensors in the pixel sensor array are capable of sensing incident light across a broad range of intensity, a high range of brightness and contrast may be achieved in images and/or video generated by the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of example circuits for a pixel sensor described herein.

FIG. 2 is a diagram of an example capacitor structure described herein.

FIGS. 3A-3L are diagrams of an example implementation of forming a capacitor structure described herein.

FIG. 4 is a diagram of an example capacitor structure described herein.

FIGS. 5A-5C are diagrams of an example implementation of forming a capacitor structure described herein.

FIG. 6 is a diagram of an example capacitor structure described herein.

FIGS. 7A-7C are diagrams of an example implementation of forming a capacitor structure described herein.

FIG. 8 is a diagram of an example capacitor structure described herein.

FIGS. 9A-9J are diagrams of an example implementation of forming a capacitor structure described herein.

FIG. 10 is a diagram of an example semiconductor device described herein.

FIG. 11 is a diagram of an example semiconductor device described herein.

FIG. 12 is a diagram of an example semiconductor device described herein.

FIGS. 13A-13C are diagrams of example top view layouts for overflow capacitors described herein.

FIG. 14 is a flowchart of an example process associated with forming a capacitor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a pixel sensor may be limited in the number of photons of incident light that can be absorbed before reaching saturation of the pixel sensor. “Saturation” refers to a level of photon absorption past which additional photons of light cannot be absorbed by the pixel sensor. Saturation of the pixel sensor results in limited dynamic range for the pixel sensor because additional brightness and color information cannot be obtained from further absorption of photons.

The amount of photocurrent charge that can be stored in a pixel sensor before reaching saturation may be referred to as the full well capacity (FWC) of the pixel sensor. The full well capacity of the pixel sensor may be based at least in part on the size (e.g., the depth, the width, the volume) of the photodiode of the pixel sensor and/or the shape of the photodiode, among other examples. However, while increasing the size of the photodiode may increase the full well capacity of the pixel sensor, doing so may come at the expense of decreasing the density of pixel sensors in the pixel sensor array, which may reduce the resolution of the pixel sensor array.

In some implementations described herein, an image sensor device (e.g., a complementary metal-oxide-semiconductor (CMOS) image sensor device) includes a capacitor structure that is configured to store charge associated with a photocurrent that is generated by a pixel sensor in a pixel sensor array of the image sensor device. The photocurrent may be transferred from the pixel sensor to the capacitor structure, which enables the pixel sensor to generate more charge for the photocurrent than if the photocurrent were wholly stored in the photodiode and/or floating diffusion node of the pixel sensor. Thus, the capacitor structure may increase the full well capacity of the pixel sensor, which may enable a higher range of brightness and/or contrast to be achieved in images and/or video generated by the pixel sensor array.

The capacitor structure is formed using techniques described herein to achieve a small lateral footprint for the capacitor structure. The capacitor structure may include a metal-insulator-metal (MIM) layer stack in which bottom electrode layers and top electrode layers are arranged in an alternating manner and separated by insulator layers. The bottom contact structure for the bottom electrode layers and the top contact structure for the top electrode layers are formed laterally adjacent to opposing ends of the MIM layer stack, as opposed to landing individual contacts on the top surfaces of each of the electrode layers (which would otherwise increase the lateral size of the capacitor structure). To electrically isolate the bottom electrode layers from the top contact structure, the ends of the bottom electrode layers facing the top contact structure are etched such that the ends of the bottom electrode layers are spaced apart from the top contact structure. Similarly, the ends of the top electrode layers facing the bottom contact structure are etched such that the ends of the top electrode layers are spaced apart from the bottom contact structure. This enables the bottom contact structure for the bottom electrode layers and the top contact structure for the top electrode layers to be formed laterally adjacent to the opposing ends of the MIM layer stack, which enables a more compact lateral footprint to be achieved for the capacitor structure. This enables a higher density of capacitor structures to be included in the image sensor device to increase the full well capacity of the pixel sensors of the image sensor device.

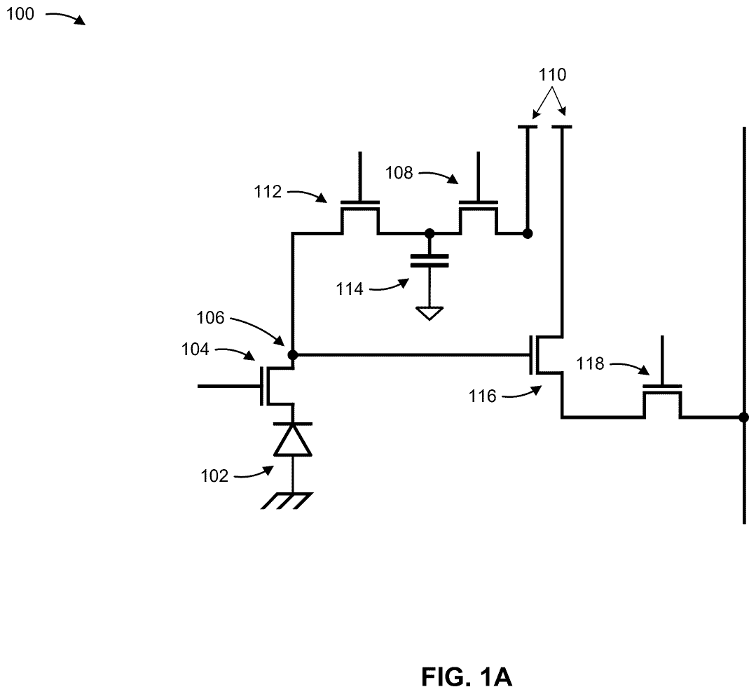

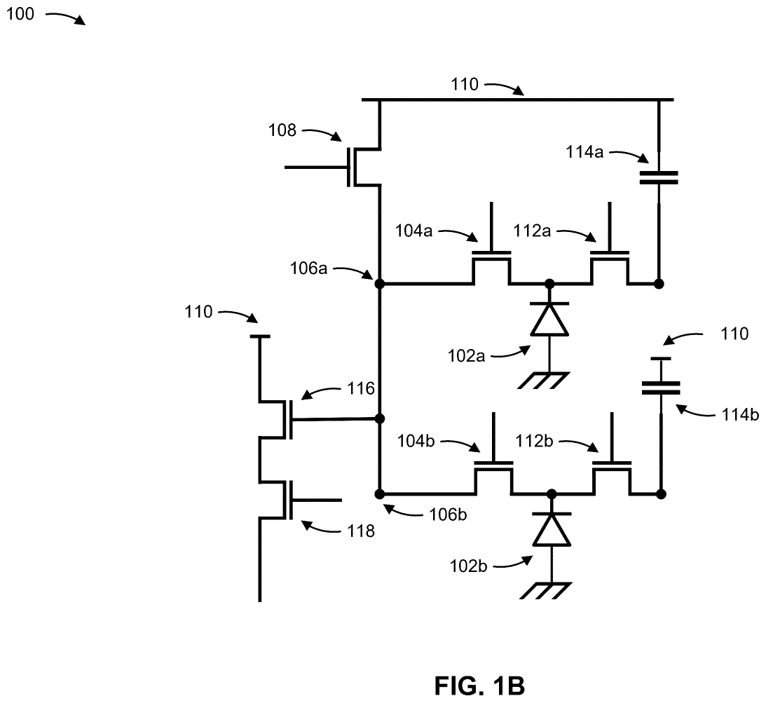

FIGS. 1A and 1B are diagrams of example circuits for a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

As shown in an example circuit in FIG. 1A, a pixel sensor 100 includes a photodiode 102 that may be configured to sense and/or accumulate incident light (e.g., light directed toward the pixel sensor 100) and convert photons of the incident light to a photocurrent. The magnitude of the photocurrent may be based on the number of photons (e.g., the intensity of the incident light) collected in the photodiode 102. Thus, the accumulation of photons in the photodiode 102 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 102 is electrically connected with a transfer gate 104. The transfer gate 104 is configured to control the transfer of the photocurrent from the photodiode to a floating diffusion node 106. The transfer gate 104 may be selectively switched by applying a transfer voltage (Vₜₓ) to the transfer gate 104. In some implementations, the transfer voltage being applied to the transfer gate 104 causes a leakage path (e.g., a buried channel) to form between the photodiode 102 and the floating diffusion node 106 across the transfer gate 104, which enables the photocurrent to traverse along the leakage path to the floating diffusion node 106. In some implementations, the transfer voltage being removed from the transfer gate 104 (or the absence of the transfer voltage) causes the leakage path to be removed, such that the photocurrent cannot pass from the photodiode 102 to the floating diffusion node 106.

The circuit for the pixel sensor 100 may further include a reset gate 108. The reset gate 108 is electrically connected to a voltage source 110. The reset gate 108 may be controlled to selectively apply a reset voltage (Vᵣₛₜ) to the floating diffusion node 106 from the voltage source 110. The transfer gate 104 and the reset gate 108 may be electrically coupled with the floating diffusion node 106 such that the reset voltage is applied to the floating diffusion node 106 to “reset” the floating diffusion node 106 (e.g., by draining any residual charge in the floating diffusion node 106) prior to activation of the transfer gate 104 to transfer a photocurrent from the photodiode 102 to the floating diffusion node 106.

The pixel sensor 100 may be a lateral overflow integration capacitor (LOFIC) pixel sensor that includes an overflow gate 112 and an overflow capacitor 114. The overflow capacitor 114 may be electrically coupled to the floating diffusion node 106 through the overflow gate 112 such that photocurrent may be transferred from the floating diffusion node 106 to the overflow capacitor 114 for temporary storage. The overflow gate 112 may selectively control the flow of photocurrent to and/or from the overflow capacitor 114. This enables additional photocurrent to be transferred to the floating diffusion node 106 from the photodiode 102 without causing the pixel sensor 100 to reach saturation, which increases the full well capacity and the dynamic range of the pixel sensor 100.

The photocurrent may be used to apply a floating diffusion voltage (V_{fd}) to a source follower gate 116 of the circuit of the pixel sensor 100. This permits the photocurrent to be observed without removing or discharging the photocurrent from the floating diffusion node 106 and/or from the overflow capacitor 114. The reset gate 108 may instead be used to remove or discharge the photocurrent from the floating diffusion node 106 and/or from the overflow capacitor 114.

To apply the floating diffusion voltage to the source follower gate 116, the transfer gate 104 may be switched off (e.g., so that the photocurrent does not flow back into the photodiode 102) and the overflow gate 112 may be switched on. This configuration enables the photocurrent stored in floating diffusion node 106 and in the overflow capacitor 114 to be used to apply the floating diffusion voltage to the source follower gate 116.

The source follower gate 116 functions as a high impedance amplifier for the pixel sensor 100. The source follower gate 116 provides a voltage-to-current conversion of the floating diffusion voltage. The output of the source follower gate 116 is electrically connected with a row select gate 118, which is configured to control the flow of the photocurrent to external circuitry. The row select gate 118 is controlled by selectively applying a select voltage (V_{di}) to the gate of the row select gate 118. This permits the photocurrent to flow to an output of the pixel sensor 100.

As shown in another example circuit in FIG. 1B, a pixel sensor 100 may include a plurality of subcircuits. The subcircuits may include a small pixel subcircuit and a large pixel subcircuit. The small pixel subcircuit may include a small photodiode 102a, a transfer gate 104a, floating diffusion node 106a, an overflow gate 112a, and an overflow capacitor 114a. The large pixel sensor subcircuit may include a large photodiode 102b, a transfer gate 104b, a floating diffusion node 106b, an overflow gate 112b, and an overflow capacitor 114b. The small pixel subcircuit and the large pixel subcircuit may both be connected to the reset gate 108, the voltage source 110, the source follower gate 116 and the row select gate 118. The large photodiode 102b may be physically larger than the small photodiode 102a, thereby enabling pixel sensor 100 to have different regions of photonic sensitivity.

As indicated above, FIGS. 1A and 1B are provided as examples. Other examples may differ from what is described with regard to FIGS. 1A and 1B.

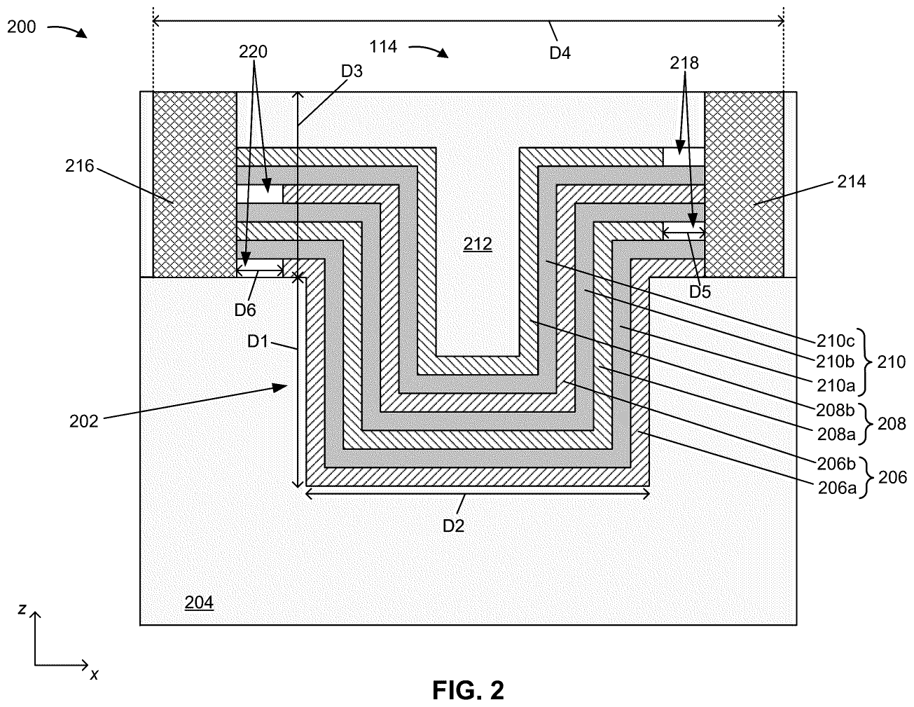

FIG. 2 is a diagram of an example capacitor structure 200 described herein. The capacitor structure 200 may include an example structural implementation of an overflow capacitor 114 of a pixel sensor 100 described herein.

As shown in FIG. 2, the capacitor structure 200 extends into a trench 202 that is formed in a dielectric layer 204. Thus, the capacitor structure 200 may be referred to as a trench capacitor structure. The dielectric layer 204 may correspond to an interlayer dielectric (ILD) layer, an intermetal dielectric (IMD) layer, an etch stop layer (ESL), another type of dielectric layer, or a combination thereof. The dielectric layer 204 may include a low dielectric constant (low-k) oxide material such as silicon oxide (SiOₓ), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable low-k dielectric material. Additionally and/or alternatively, the dielectric layer 204 may include an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples. Additionally and/or alternatively, the dielectric layer 204 may include a high dielectric constant (high-k) dielectric material such as a silicon nitride (SiₓN_{y}), silicon carbide (SiC), silicon oxynitride (SiON), hafnium oxide (HfOₓ), and/or another suitable high-k dielectric material.

The trench 202 may have a vertical (z-direction) depth (indicated in FIG. 2 as dimension D1) and a lateral (x-direction) width (indicated in FIG. 2 as dimension D2). In some implementations, the vertical depth of the trench 202 is included in a range of approximately 0.23 microns to approximately 0.27 microns. However, other values and ranges are within the scope of the present disclosure. In some implementations, the lateral width of the trench 202 is included in a range of approximately 0.19 microns to approximately 0.21 microns. However, other values and ranges are within the scope of the present disclosure.

In some implementations, the trench 202 may have a high aspect ratio, which is a ratio of the vertical depth (dimension D1) to the lateral width (dimension D2). In these implementations, the capacitor structure 200 may be referred to as a deep trench capacitor (DTC) structure. In some implementations, the aspect ratio of the trench 202 (e.g., the ratio of D1:D2) may be approximately 10:1 or greater. In some implementations, the trench 202 may have an aspect ratio that is included in the range of approximately 20:1 to approximately 50:1. However, other values and ranges are within the scope of the present disclosure.

As further shown in FIG. 2, the capacitor structure includes a plurality of first electrode layers 206 (e.g., bottom electrode layers or capacitor bottom metal (CBM) layers), a plurality of second electrode layers 208 (e.g., top electrode layers or capacitor top metal (CTM) layers), and a plurality of insulator layers 210. The first electrode layers 206, the second electrode layers 208, and the insulator layers 210 are arranged in an MIM stack in the capacitor structure 200. The MIM stack includes a repeating arrangement of a first electrode layer 206, an insulator layer 210 on the first electrode layer 206, and a second electrode layer 208 on the insulator layer 210. For example, a first electrode layer 206a may be located on the sidewalls and on the bottom of the trench 202, an insulator layer 210a may be located on the first electrode layer 206a, a second electrode layer 208a may be located on the insulator layer 210a, another insulator layer 210b may be located on the second electrode layer 208a, another first electrode layer 206b may be located on the insulator layer 210b, another insulator layer 210c may be located on the first electrode layer 206b, and another second electrode layer 208b may be located on the insulator layer 210c. The quantity of first electrode layers 206, the quantity of second electrode layers 208, and the quantity of insulator layers 210 illustrated in FIG. 2 is an example, and other quantities are within the scope of the present disclosure.

The first electrode layers 206, the second electrode layers 208, and the insulator layers 210 may each include conformal layers that conform to the profile of the trench 202. In other words, the first electrode layers 206, the second electrode layers 208, and the insulator layers 210 may each extend along the sidewalls of the trench 202, and along the bottom surface of the trench 202. The remaining area in the trench 202 may be filled in with a dielectric layer 212.

The first electrode layers 206 and the second electrode layers 208 may each have a thickness that is included in a range of approximately 200 angstroms to approximately 500 angstroms. However, other values for the range are within the scope of the present disclosure. The first electrode layers 206 and the second electrode layers 208 may include one or more electrically conductive materials, such as molybdenum (Mo), chromium (Cr), titanium nitride (TIN), tantalum nitride (TaN), titanium (Ti). aluminum (Al), gold (Au), silver (Ag), cobalt (Co), copper (Cu), ruthenium (Ru), platinum (Pt), and/or another suitable electrically conductive material. The insulator layers 210 may include one or more low-k dielectric materials, one or more high-k dielectric materials, and/or another type of electrically insulating material. Examples include zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layers 210 each include a multiple-layer stack that includes a plurality of dielectric layers. For example, an insulator layer 210 may include a ZrO₂/Al₂O₃/ZrO₂ (ZAZ) layer stack.

As further shown in FIG. 2, the first electrode layers 206, the second electrode layers 208, and the insulator layers 210 may extend above the trench 202 in a z-direction and laterally outward from the trench in an x-direction. The portions of the first electrode layers 206 that extend laterally outward from the trench 202 along the surface of the dielectric layer 204 may be electrically connected and/or physically connected to a first contact structure 214. In particular, the ends of the portions of the first electrode layers 206 that extend laterally outward from the trench 202 along the surface of the dielectric layer 204 may be electrically connected and/or physically connected to a side of the first contact structure 214. The portions of the second electrode layers 208 that extend laterally outward from the trench 202 along the surface of the dielectric layer 204 may be electrically connected and/or physically connected to a second contact structure 216. In particular, the ends of the portions of the second electrode layers 208 that extend laterally outward from the trench 202 along the surface of the dielectric layer 204 may be electrically connected and/or physically connected to a side of the second contact structure 216.

The first contact structure 214 and the second contact structure 216 may be located laterally adjacent to opposing sides of the trench 202. Thus, the ends of the first electrode layers 206 may be electrically connected and/or physically connected to the first contact structure 214 at a first side of the trench 202, and the ends of the second electrode layers 208 may be electrically connected and/or physically connected to the second contact structure 216 at a second side of the trench 202 opposing the first side. The first contact structure 214 and the second contact structure 216 may each have a vertical (z-direction) height (indicated in FIG. 2 as dimension D3) that is included in a range of approximately 0.7 microns to approximately 0.8 microns. However, other values and ranges are within the scope of the present disclosure.

At the first side of the trench 202, airgaps 218 are included between the ends of the second electrode layers 208 and the side of the first contact structure 214 so that the second electrode layers 208 and the first contact structure 214 are electrically isolated from each other at the first end. At the second side of the trench 202, airgaps 220 are included between the ends of the first electrode layers 206 and the side of the second contact structure 216 so that the first electrode layers 206 and the second contact structure 216 are electrically isolated from each other at the second end.

The electrical isolation provided by the airgaps 218 enables the first electrode layers 206 to be coupled to the side of the first contact structure 214, as opposed to having individual contacts that land on each of the first electrode layers 206. Similarly, the electrical isolation provided by the airgaps 220 enables the second electrode layers 208 to be coupled to the side of the second contact structure 216, as opposed to having individual contacts that land on each of the second electrode layers 208. This enables the overall lateral size (indicated in FIG. 2 as dimension D4) of the capacitor structure 200 to be smaller than if individual contact structures were landed on each of the first electrode layers 206 and each of the second electrode layers 208, because minimum spacing rules would need to be followed for the individual contact structures. As an example, the overall lateral width (dimension D4) of the capacitor structure 200 may be included in a range of approximately 1 micron to approximately 2 microns, whereas the overall lateral width of a capacitor structure in which individual contact structures are landed on the electrode layers may be included in a range of approximately 7 microns to approximately 8 microns. However, other values and ranges for the lateral width of the capacitor structure 200 are within the scope of the present disclosure.

In some implementations, the lateral width of the airgaps 218 (indicated in FIG. 2 as dimension D5) is included in a range of approximately 0.2 microns to approximately 0.4 microns. The likelihood of leakage between the second electrode layers 208 and the first contact structure 214 may increase if the lateral width of the airgaps 218 is less than approximately 0.2 microns. The capacitance of the capacitor structure 200 may be reduced if the lateral width of the airgaps 218 is greater than approximately 0.4 microns (e.g., if the ends of the second electrode layers 208 are cut back further to increase the lateral width of the airgaps 218), and/or the overall lateral width of the capacitor structure 200 may be increased if the lateral width of the airgaps 218 is greater than approximately 0.4 microns (e.g., if the first contact structure 214 is moved further away from the trench 202 to increase the lateral width of the airgaps 218). If the lateral width of the airgaps 218 is included in the range of approximately 0.2 microns to approximately 0.4 microns, sufficient electrical isolation between the second electrode layers 208 and the first contact structure 214 may be provided, and a high capacitance and small lateral footprint may be achieved for the capacitor structure 200. However, other values, and ranges other than approximately 0.2 microns to approximately 0.4 microns, for the lateral width of the airgaps 218 are within the scope of the present disclosure.

In some implementations, the lateral width of the airgaps 220 (indicated in FIG. 2 as dimension D6) is included in a range of approximately 0.2 microns to approximately 0.4 microns. The likelihood of leakage between the first electrode layers 206 and the second contact structure 216 may increase if the lateral width of the airgaps 220 is less than approximately 0.2 microns. The capacitance of the capacitor structure 200 may be reduced if the lateral width of the airgaps 220 is greater than approximately 0.4 microns (e.g., if the ends of the first electrode layers 206 are cut back further to increase the lateral width of the airgaps 220), and/or the overall lateral width of the capacitor structure 200 may be increased if the lateral width of the airgaps 220 is greater than approximately 0.4 microns (e.g., if the second contact structure 216 is moved further away from the trench 202 to increase the lateral width of the airgaps 220). If the lateral width of the airgaps 220 is included in the range of approximately 0.2 microns to approximately 0.4 microns, sufficient electrical isolation between the first electrode layers 206 and the second contact structure 216 may be provided, and a high capacitance and small lateral footprint may be achieved for the capacitor structure 200. However, other values, and ranges other than approximately 0.2 microns to approximately 0.4 microns, for the lateral width of the airgaps 220 are within the scope of the present disclosure.

In some implementations, the airgaps 218 and 220 are filled with a dielectric gas such as air. In some implementations, the airgaps 218 and 220 are filled with an electrically inert gas such as a noble gas (e.g., argon (Ar) or helium (He), among other examples). In some implementations, the airgaps 218 and 220 may have a dielectric constant that is approximately equal to 1. In some implementations, the airgaps 218 and 220 may have a dielectric constant that is included in a range of approximately 1 to approximately 2. However, other values and ranges are within the scope of the present disclosure.

Thus, the capacitor structure 200 may include a plurality of first electrode layers 206 and a plurality of second electrode layers 208 that extend along sidewalls and a bottom surface of the trench 202, where the plurality of first electrode layers 206 and the plurality of second electrode layers 208 are arranged in an alternating manner in the trench 202. First ends of the plurality of first electrode layers 206 extend laterally outward from a first side of the trench 202, and second ends of the plurality of second electrode layers 208 extend laterally outward from a second side of the trench 202 (e.g., opposing the first side). The capacitor structure 200 may include a first contact structure 214 in contact with the first ends of the plurality of first electrode layers 206, and a second contact structure 216 in contact with the second ends of the plurality of second electrode layers 208. Airgaps 218 are included between third ends (e.g., opposing the second ends) of the plurality of second electrode layers 208 and the first contact structure 214 such that the plurality of second electrode layers 208 and the first contact structure 214 are spaced apart from each other. Airgaps 220 are included between fourth ends (e.g., opposing the first ends) of the plurality of first electrode layers 206 and the second contact structure 216 such that the plurality of first electrode layers 206 and the second contact structure 216 are spaced apart from each other.

As indicated above, FIG. 2 is provided as an example. Other examples may differ from what is described with regard to FIG. 2.

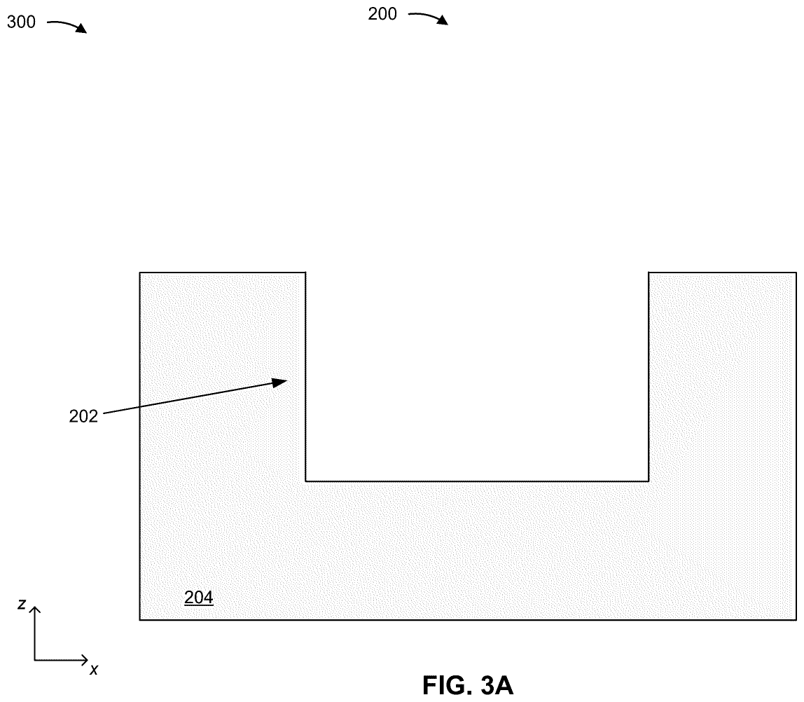

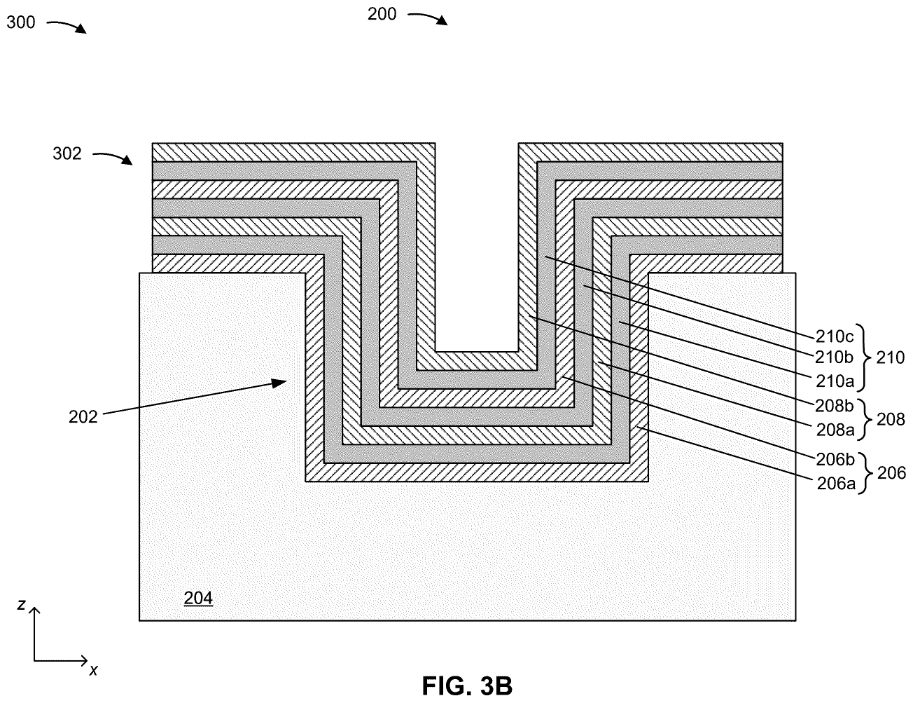

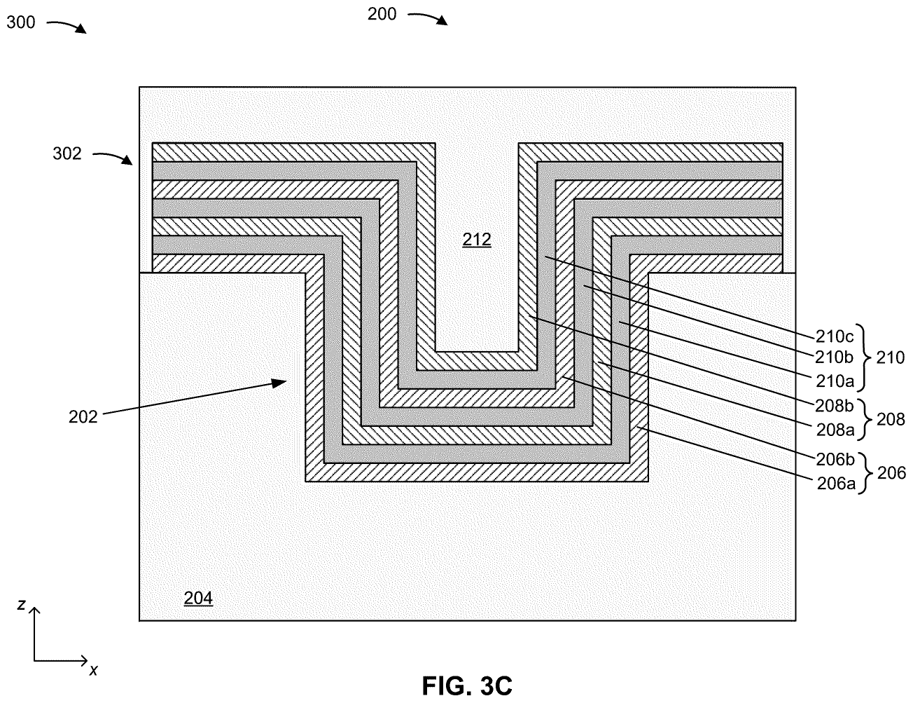

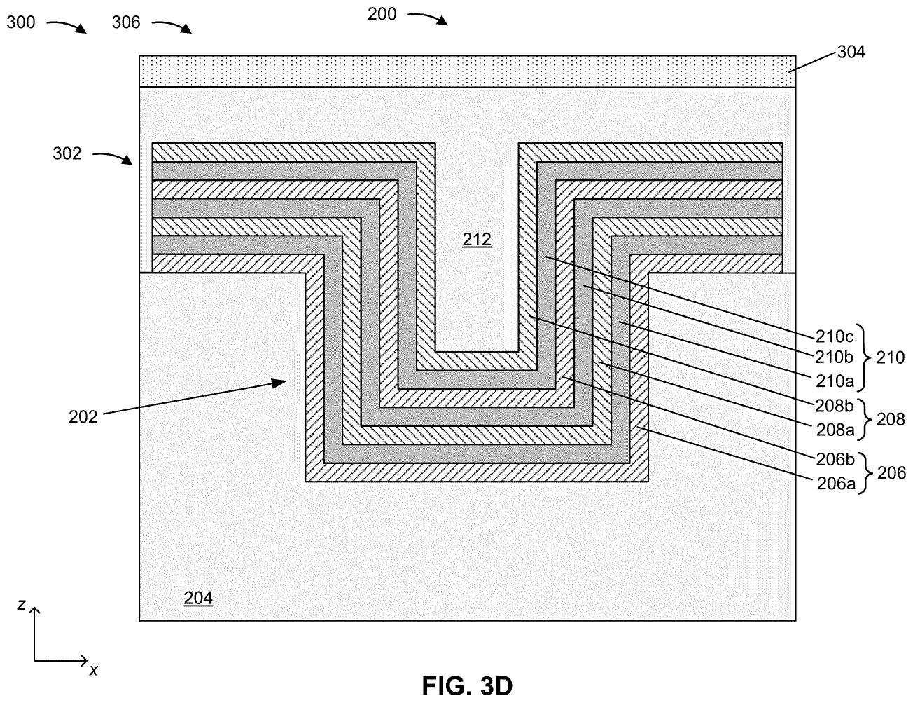

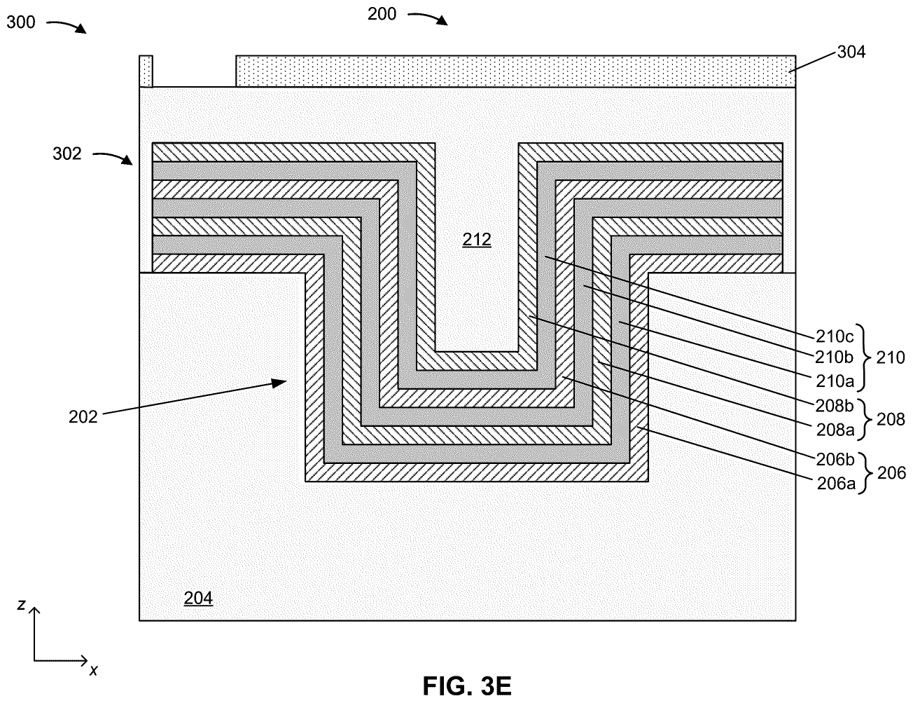

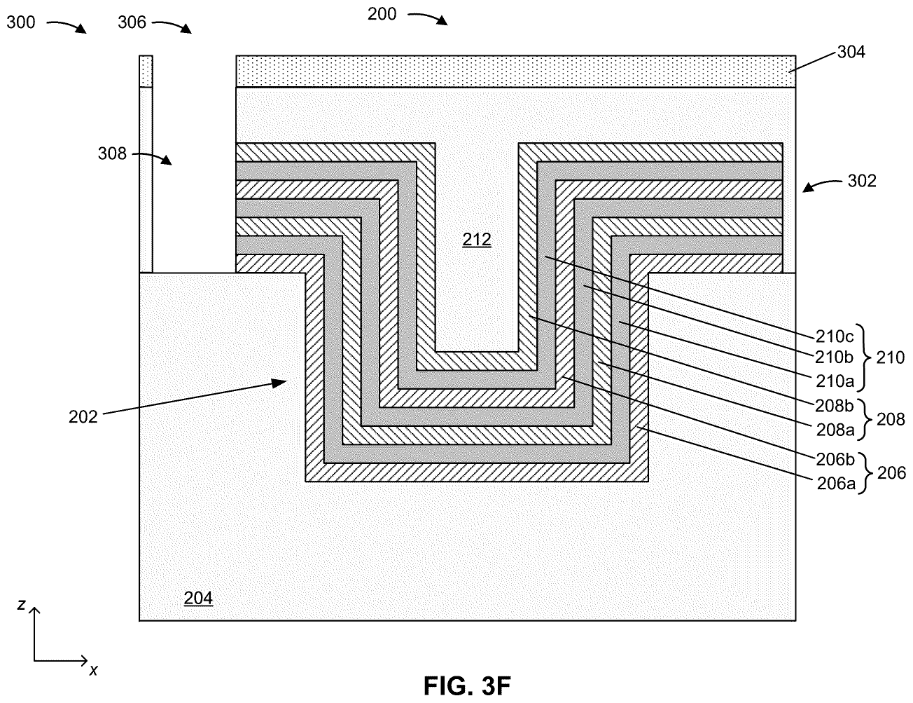

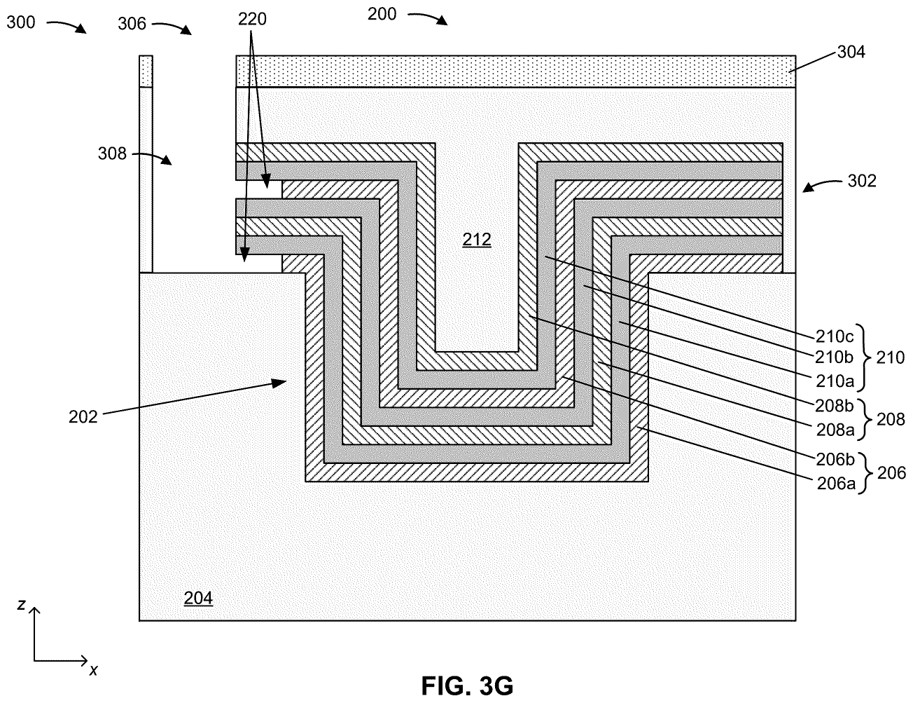

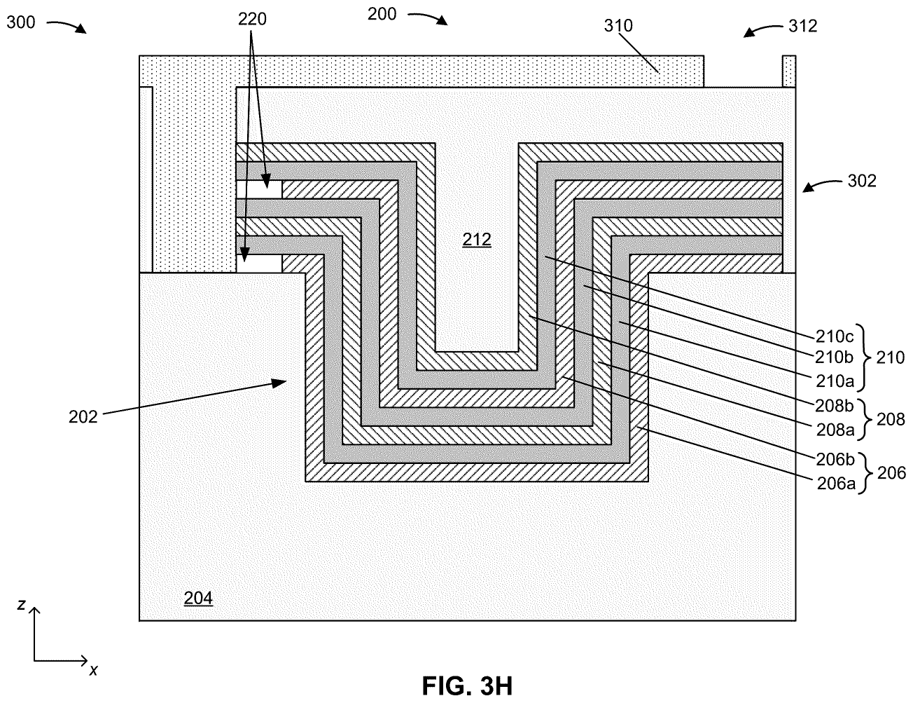

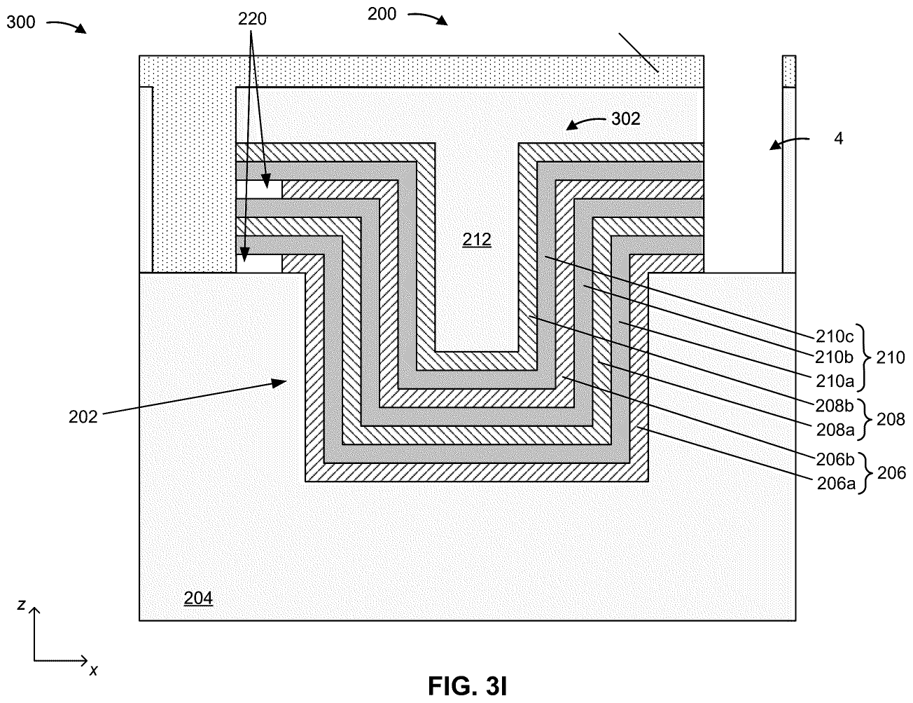

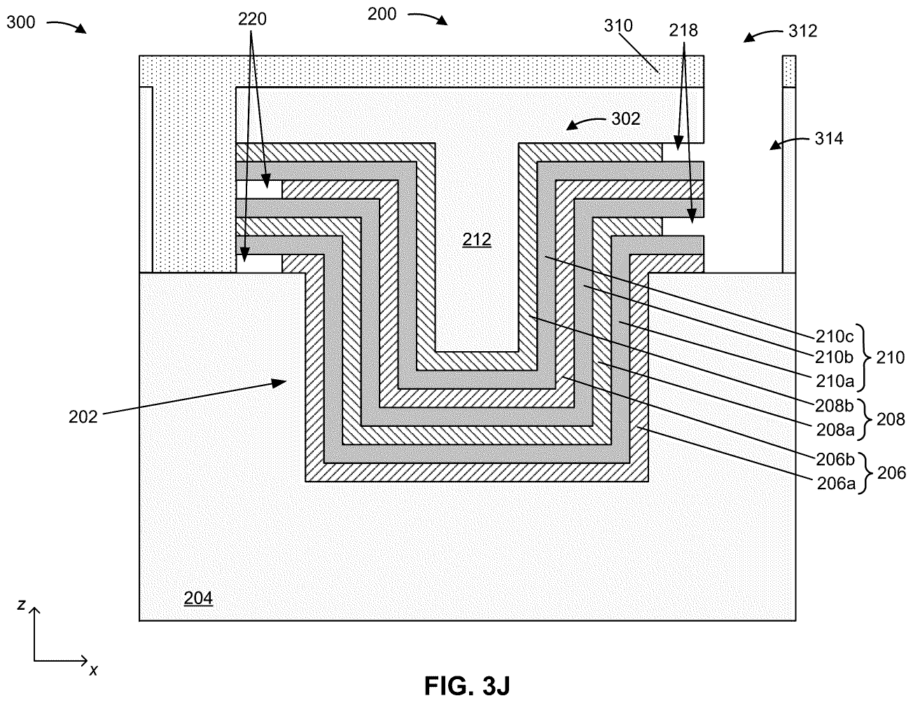

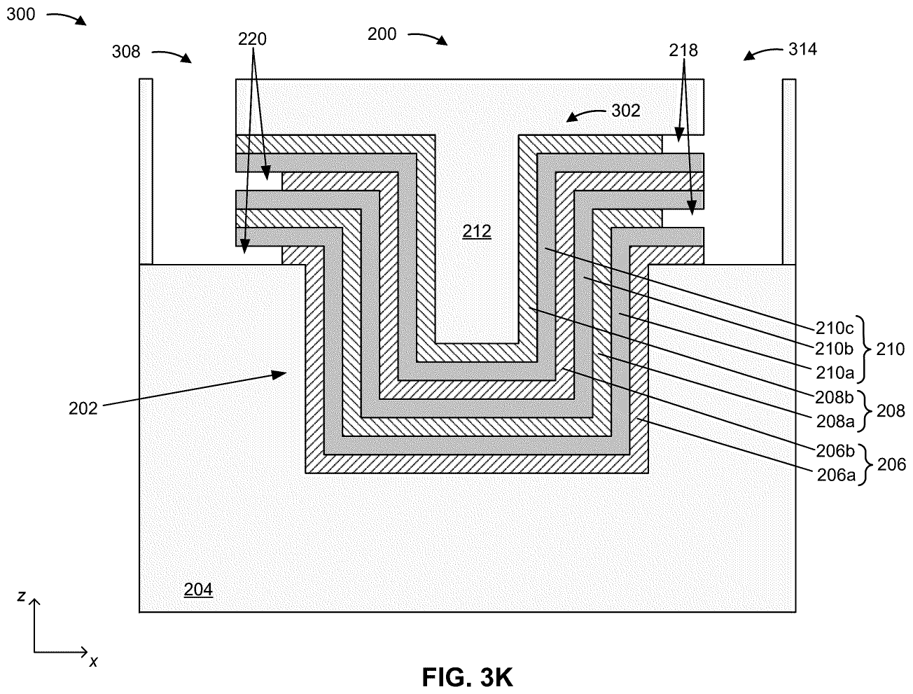

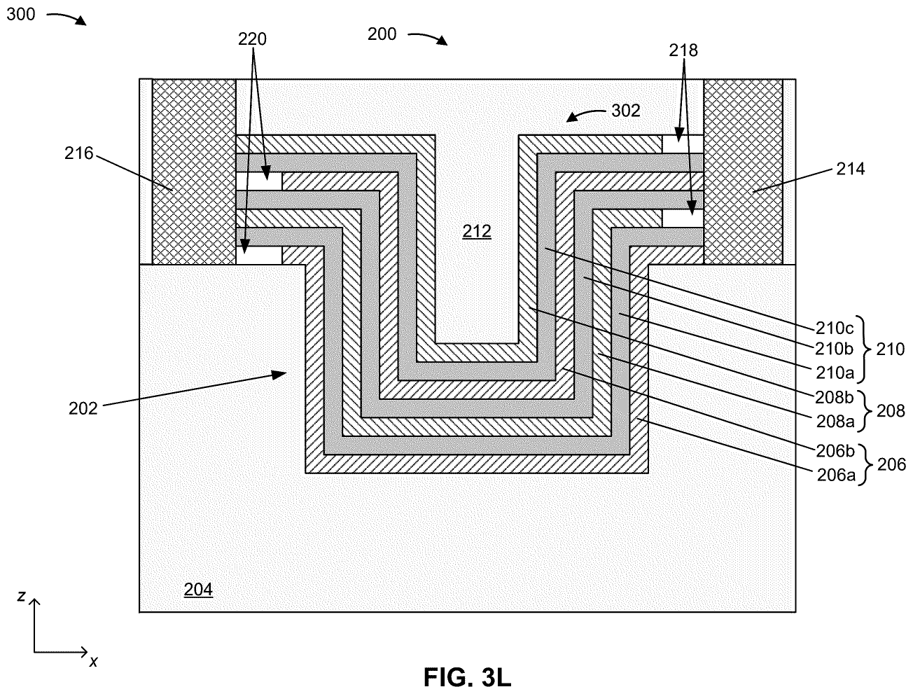

FIGS. 3A-3L are diagrams of an example implementation 300 of forming a capacitor structure 200 described herein. In some implementations, one or more of the semiconductor processing operations described in connection with FIGS. 3A-3L may be performed using one or more semiconductor processing tools, such as a deposition tool, an exposure tool, a developer tool, an etch tool, a planarization tool, a wafer/die transport tool, and/or another type of semiconductor processing tool.

As shown in FIG. 3A, the trench 202 may be formed in the dielectric layer 204. In some implementations, a pattern in a photoresist layer is used to etch the dielectric layer 204 to form the trench 202. In these implementations, a deposition tool may be used to form the photoresist layer on the dielectric layer 204 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 204 based on the pattern to form the trench 202. In some implementations, a photoresist removal tool may be used to remove the remaining portions of the photoresist layer (e.g., using a chemical stripper, plasma ashing, and/or another technique).

Alternatively, one or more hard mask layers may be formed on the dielectric layer 204, and the pattern in the photoresist layer may be transferred to the hard mask layer(s). An etch tool may be used to etch the dielectric layer 204 based on the pattern in the hard mask layer(s) (alone or in combination with the pattern in the photoresist layer) to form the trench 202.

In some implementations, the etch operation includes a dry etch operation. For example, the trench 202 may be formed by performing a plasma-based etch operation, a gas-based etch operation, and/or another type of dry etch operation. In some implementations, the trench 202 is formed using a dry etch technique such as reactive ion etching (RIE) or deep reactive ion etching (sometimes referred to as the “Bosch process”) to achieve highly vertical sidewalls for the trench 202 with minimal sidewall taper. Additionally and/or alternatively, a wet chemical etch operation and/or another type of etch operation is performed to form the trench 202. An angle between the sidewalls of the trench 202 and the bottom surface of the trench may be approximately 90 degrees. Alternatively, the angle between the sidewalls of the trench 202 and the bottom surface of the trench may be a reentrant angle (e.g., <90 degrees) or a retrograde angle (e.g., >90 degrees).

As shown in FIG. 3B, the MIM layer stack 302 of the capacitor structure 200 is formed. A portion of the MIM layer stack 302 is formed in the trench 202 such that the first electrode layers 206, the second electrode layers 208, and the insulator layers 210 of the MIM layer stack 302 conform to the sidewalls and the bottom surface of the trench 202. Other portions of the MIM layer stack 302 are formed such that the first electrode layers 206, the second electrode layers 208, and the insulator layers 210 of the MIM layer stack 302 extend out of and laterally outward from the trench 202 along the top surface of the dielectric layer 204. The MIM layer stack 302 may resemble an upside-down omega (Ω) shape. In some implementations, the ends of the MIM layer stack 302 are etched to define the lateral width (or length) of the capacitor structure 200.

In some implementations, a conformal deposition technique such as chemical vapor deposition (CVD) and/or atomic layer deposition (ALD) may be used to deposit the first electrode layers 206, the second electrode layers 208, and the insulator layers 210 of the MIM layer stack 302. One or more deposition tools may be used to deposit the first electrode layer 206a on the sidewalls and on the bottom of the trench 202 (as well as along the top surface of the dielectric layer 204), may be used to deposit the insulator layer 210a on the first electrode layer 206a, may be used to deposit the second electrode layer 208a on the insulator layer 210a, may be used to deposit the insulator layer 210b on the second electrode layer 208a, may be used to deposit the first electrode layer 206b on the insulator layer 210b, may be used to deposit the insulator layer 210c on the first electrode layer 206b, and/or may be used to deposit the second electrode layer 208b on the insulator layer 210c.

As shown in FIG. 3C, the remaining area in the trench 202 may be filled in with the dielectric layer 212. The dielectric layer 212 may also be deposited over the MIM layer stack 302. A deposition tool may be used to deposit the dielectric layer 212 using a physical vapor deposition (PVD) technique, an ALD technique, a CVD technique, an oxidation technique, and/or another suitable deposition technique. The dielectric layer 212 may be deposited in one or more deposition operations. In some implementations, a planarization tool may be used to perform a planarization operation (e.g., a chemical mechanical planarization (CMP) operation) to planarize the dielectric layer 212 after the dielectric layer 212 is deposited.

As shown in FIGS. 3D and 3E, a masking layer 304 may be formed on the dielectric layer 212 and patterned. In some implementations, the masking layer 304 includes a photoresist layer. In these implementations, a deposition tool may be used to form the masking layer 304 on the dielectric layer 212 (e.g., using a spin-coating technique and/or another suitable deposition technique), an exposure tool may be used to expose the masking layer 304 to a radiation source to pattern the masking layer 304, and a developer tool may be used to develop and remove portions of the masking layer 304 to expose the pattern. In some implementations, the masking layer 304 includes a hard mask layer, and the pattern is formed in the masking layer 304 using a patterned photoresist layer. The pattern in the masking layer 304 may include an opening 306 over an end of the MIM layer stack 302.

As shown in FIG. 3F, an etch tool may be used to etch the ends of the first electrode layers 206, the second electrode layers 208, and the insulator layers 210 of the MIM layer stack 302 based on the opening 306 in the masking layer 304 to form a recess 308. In some implementations, the etch operation includes a dry etch operation (e.g., a plasma-based etch operation, a gas-based etch operation), a wet chemical etch operation, and/or another type of etch operation.

As shown in FIG. 3G, another etch operation is performed to etch back the ends of the first electrode layers 206 that are exposed in the recess 308 to form the airgaps 220. The etch operation may include a wet chemical etch operation in which a wet etchant is used to selectively etch the ends of the first electrode layers 206 with minimal to no etching of the ends of the second electrode layers 208, the ends of the insulator layers 210, and the dielectric layer 212. Thus, the wet etchant may have a greater etch rate for the material of the first electrode layers 206 than the respective etch rates of the wet etchant for material of the second electrode layers 208, the material of the insulator layers 210, and the material of the dielectric layer 212.

As an example, the material of the first electrode layers 206 may include chromium (Cr), the material of the second electrode layers 208 may include molybdenum (Mo), and the material of the insulator layers 210 may include aluminum oxide (Al₂O₃). A chromium wet etchant that includes a mixture of perchloric acid (HClO₄) and ceric ammonium nitrate ((NH₄)₂[Ce(NO₃)₆]) may be used to etch the first electrode layers 206. The etch rate of the chromium wet etchant for the chromium of the first electrode layers 206 may be approximately 36 times to approximately 16,000 times greater than the etch rate of the chromium wet etchant for the molybdenum of the second electrode layers 208 and for the aluminum oxide of the insulator layers 210. However, other types of etchants, and other etch rate ranges, are within the scope of the present disclosure.

As another example, the material of the first electrode layers 206 may include gold (Au), the material of the second electrode layers 208 may include titanium nitride (TiN), and the material of the insulator layers 210 may include silicon nitride (Si₃N₄). A gold wet etchant that includes a mixture of nitric acid (HNO₃) and hydrochloric acid (HCl) may be used to etch the first electrode layers 206. In some implementations, the mixture of nitric acid and hydrochloric acid is diluted in water (H₂O). The etch rate of the gold wet etchant for the gold of the first electrode layers 206 may be at least approximately 1,300 times greater than the etch rate of the gold wet etchant for the titanium nitride of the second electrode layers 208 and for the silicon nitride of the insulator layers 210. However, other types of etchants, and other etch rate ranges, are within the scope of the present disclosure.

A photoresist removal tool may be used to remove the remaining portions of the masking layer 304 (e.g., using a chemical stripper, plasma ashing, and/or another technique) after the ends of the first electrode layers 206 are etched back.

As shown in FIG. 3H, the recess 308 is filled in with another masking layer 310 that is also formed over the dielectric layer 212. The masking layer 310 may be formed in a similar manner as the masking layer 304, and an opening 312 through the masking layer 310 over the ends of the MIM layer stack 302 at an opposing side of the trench 202 is formed in a similar manner as the opening 306.

As shown in FIG. 3I, an etch tool may be used to etch the ends of the first electrode layers 206, the second electrode layers 208, and the insulator layers 210 of the MIM layer stack 302 based on the opening 312 in the masking layer 310 to form a recess 314. In some implementations, the etch operation includes a dry etch operation (e.g., a plasma-based etch operation, a gas-based etch operation), a wet chemical etch operation, and/or another type of etch operation.

As shown in FIG. 3J, another etch operation is performed to etch back the ends of the second electrode layers 208 that are exposed in the recess 314 to form the airgaps 218. The etch operation may include a wet chemical etch operation in which a wet etchant is used to selectively etch the ends of the second electrode layers 208 with minimal to no etching of the ends of the first electrode layers 206, the ends of the insulator layers 210, and the dielectric layer 212. Thus, the wet etchant may have a greater etch rate for the material of the second electrode layers 208 than the respective etch rates of the wet etchant for material of the first electrode layers 206, the material of the insulator layers 210, and the material of the dielectric layer 212.

As an example, the material of the first electrode layers 206 may include chromium (Cr), the material of the second electrode layers 208 may include molybdenum (Mo), and the material of the insulator layers 210 may include aluminum oxide (Al₂O₃). A molybdenum wet etchant that includes nitric acid (HNO₃) may be used to etch the second electrode layers 208. In some implementations, the molybdenum wet etchant includes a mixture of nitric acid and ammonium fluoride (NH₄F) that is diluted in water (H₂O). The etch rate of the molybdenum wet etchant for the molybdenum of the second electrode layers 208 may be approximately 90 times to approximately 200 times greater than the etch rate of the molybdenum wet etchant for the chromium of the first electrode layers 206 and for the aluminum oxide of the insulator layers 210. However, other types of etchants, and other etch rate ranges, are within the scope of the present disclosure.

As another example, the material of the first electrode layers 206 may include gold (Au), the material of the second electrode layers 208 may include titanium nitride (TiN), and the material of the insulator layers 210 may include silicon nitride (Si₃N₄). A titanium nitride wet etchant that includes a hydrofluoric (HF) acid may be used to etch the second electrode layers 208. The etch rate of the titanium nitride wet etchant for the titanium nitride of the second electrode layers 208 may be at least approximately 180 times greater than the etch rate of the titanium nitride wet etchant for the gold of the first electrode layers 206 and for the silicon nitride of the insulator layers 210. However, other types of etchants, and other etch rate ranges, are within the scope of the present disclosure.

As shown in FIG. 3K, a photoresist removal tool may be used to remove the remaining portions of the masking layer 310 (e.g., using a chemical stripper, plasma ashing, and/or another technique) after the ends of the second electrode layers 208 are etched back.

As shown in FIG. 3L, the recesses 308 and 314 are respectively filled in with the materials of the second contact structure 216 and the first contact structure 214. The recess 308 is filled in such that the sidewall of the second contact structure 216 is physically coupled with the ends of the second electrode layers 208 that were exposed through the recess 308, and such that the airgaps 220 remain between the sidewall of the second contact structure 216 and the ends of the first electrode layers 206. The recess 314 is filled in such that the sidewall of the first contact structure 214 is physically coupled with the ends of the first electrode layers 206 that were exposed through the recess 314, and such that the airgaps 218 remain between the sidewall of the first contact structure 214 and the ends of the second electrode layers 208.

A deposition tool may be used to deposit the first contact structure 214 and the second contact structure 216. In some implementations, a PVD technique is used to deposit the first contact structure 214 and the second contact structure 216. The PVD technique may result in a lower step coverage than other deposition techniques such as CVD, so that minimal to no material of the first contact structure 214 is deposited into the airgaps 218, and such that minimal to no material of the second contact structure 216 is deposited into the airgaps 220. However, other deposition techniques may be used to deposit the first contact structure 214 and/or the second contact structure 216.

The first contact structure 214 and the second contact structure 216 may be deposited in one or more deposition operations. In some implementations, a seed layer is first deposited, and the first contact structure 214 and/or the second contact structure 216 is deposited on the seed layer. In some implementations, a liner is first deposited (e.g., an adhesion liner, a barrier liner), and the first contact structure 214 and/or the second contact structure 216 is then deposited on the liner. The liner may include a tantalum nitride (TaN) liner, a titanium nitride (TiN) liner, and/or another type of liner. In some implementations, a planarization tool is used to perform a planarization operation (e.g., a CMP operation) to planarize the first contact structure 214 and the second contact structure 216 after the first contact structure 214 and the second contact structure 216 are deposited.

As indicated above, FIGS. 3A-3L are provided as an example. Other examples may differ from what is described with regard to FIGS. 3A-3L.

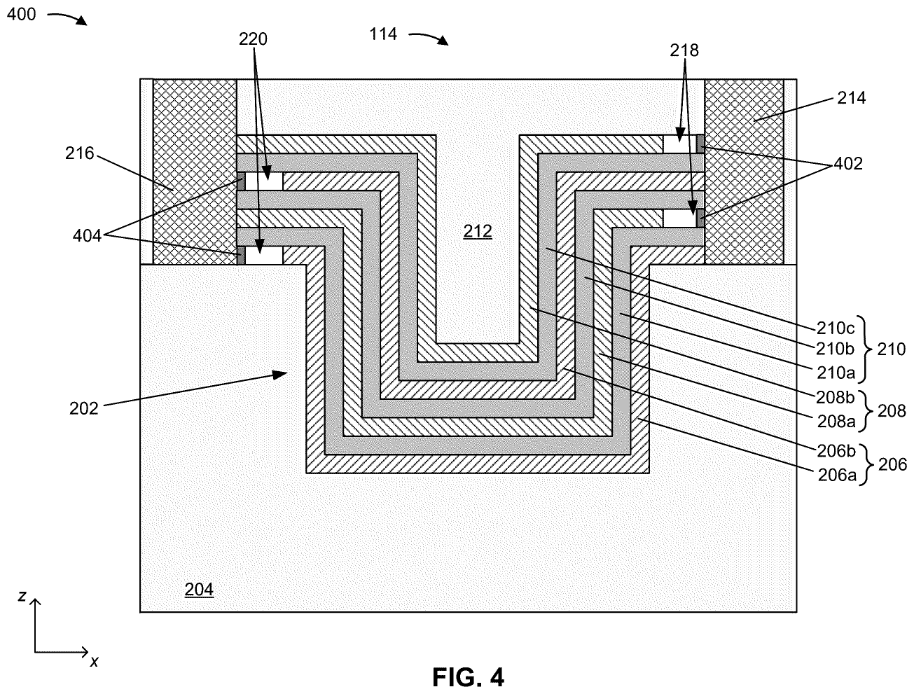

FIG. 4 is a diagram of an example capacitor structure 400 described herein. The capacitor structure 400 may include an example structural implementation of an overflow capacitor 114 of a pixel sensor 100 described herein. As shown in FIG. 4, the capacitor structure 400 includes a similar combination and arrangement of layers and/or structures 202-220 as the capacitor structure 200. However, the capacitor structure 400 further includes barrier layers 402 between the airgaps 218 and the first contact structure 214, and/or barrier layers 404 between the airgaps 220 and the second contact structure 216.

The barrier layers 402 may be included between the ends of vertically adjacent insulator layers 210, and may be included to provide structural support for the ends of the insulator layers 210 and first electrode layers 206. The barrier layers 402 may include electrically conductive materials such as tantalum nitride (TaN) and/or titanium nitride (TiN), and may effectively extend the area of the first contact structure 214, thereby reducing the contact resistance of the first contact structure 214.

Similarly, the barrier layers 404 may be included between the ends of vertically adjacent insulator layers 210, and may be included to provide structural support for the ends of the insulator layers 210 and second electrode layers 208 and/or to provide additional electrical isolation between the ends of the first electrode layers 206 and the second contact structure 216. The barrier layers 404 may include electrically conductive materials such as tantalum nitride (TaN) and/or titanium nitride (TiN), and may effectively extend the area of the second contact structure 216, thereby reducing the contact resistance of the second contact structure 216.

As indicated above, FIG. 4 is provided as an example. Other examples may differ from what is described with regard to FIG. 4.

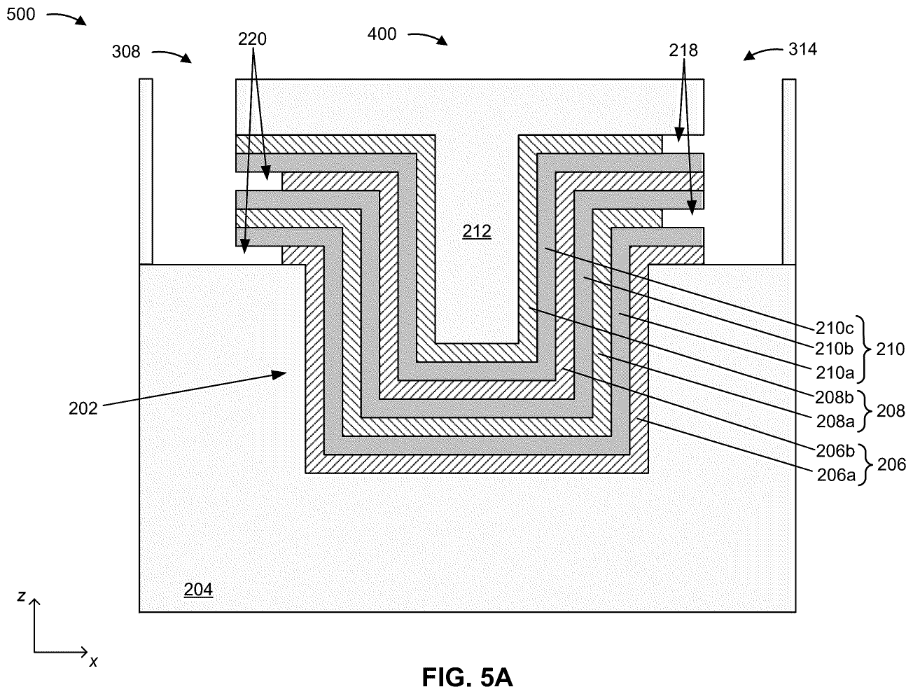

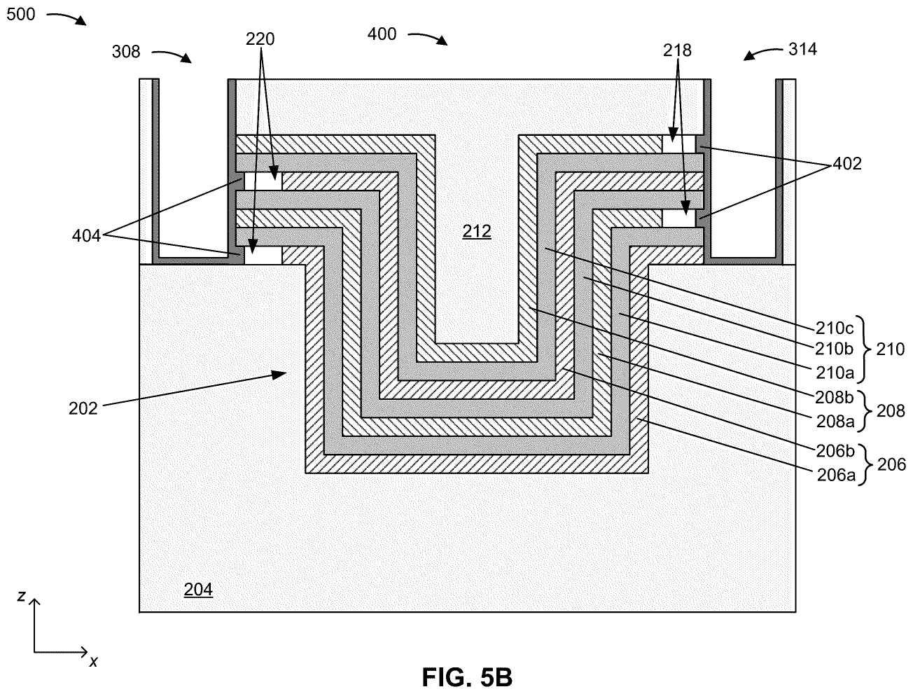

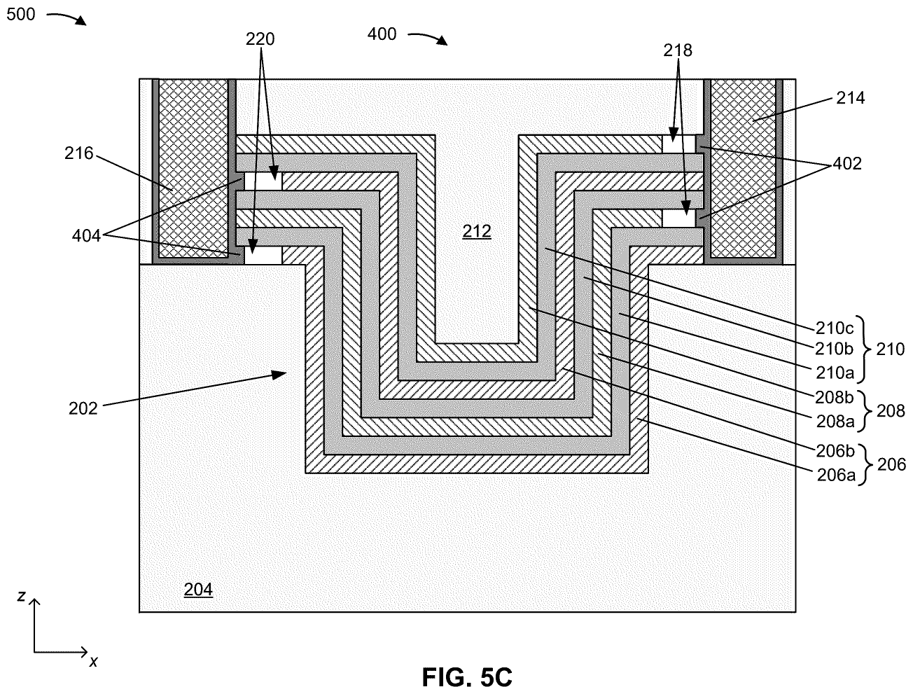

FIGS. 5A-5C are diagrams of an example implementation 500 of forming a capacitor structure 400 described herein. In some implementations, one or more of the semiconductor processing operations described in connection with FIGS. 5A-5C may be performed using one or more semiconductor processing tools, such as a deposition tool, an exposure tool, a developer tool, an etch tool, a planarization tool, a wafer/die transport tool, and/or another type of semiconductor processing tool.

As shown in FIG. 5A, similar processing operations as described in connection with FIGS. 3A-3K may be performed to form the trench 202, to form the MIM layer stack 302 including the first electrode layers 206, the second electrode layers 208, and the insulator layers 210, and to form the dielectric layer 212. Moreover, similar processing operations as described in connection with FIGS. 3A-3K may be performed to form the recesses 308 and 314, to etch the ends of the second electrode layers 208 to form the airgaps 218, and to etch the ends of the first electrode layers 206 to form the airgaps 220.

As shown in FIG. 5B, the barrier layers 402 and 404 may be respectively formed in the recesses 314 and 308. A deposition tool may be used to deposit the barrier layers 402 and 404 using a conformal deposition technique such as CVD and/or ALD. In this way, the barrier layer 402 conforms to the sidewalls and bottom surface of the recess 314, and extends into the airgaps 218. Moreover, the barrier layer 404 conforms to the sidewalls and bottom surface of the recess 308, and extends into the airgaps 220.

As shown in FIG. 5C, the first contact structure 214 is then deposited on the barrier layer 402 in the recess 314, and the second contact structure 216 is deposited on the barrier layer 404 in the recess 308. The first contact structure 214 and the second contact structure 216 may be deposited and planarized in a similar manner as described in connection with FIG. 3L.

As indicated above, FIGS. 5A-5C are provided as an example. Other examples may differ from what is described with regard to FIGS. 5A-5C.

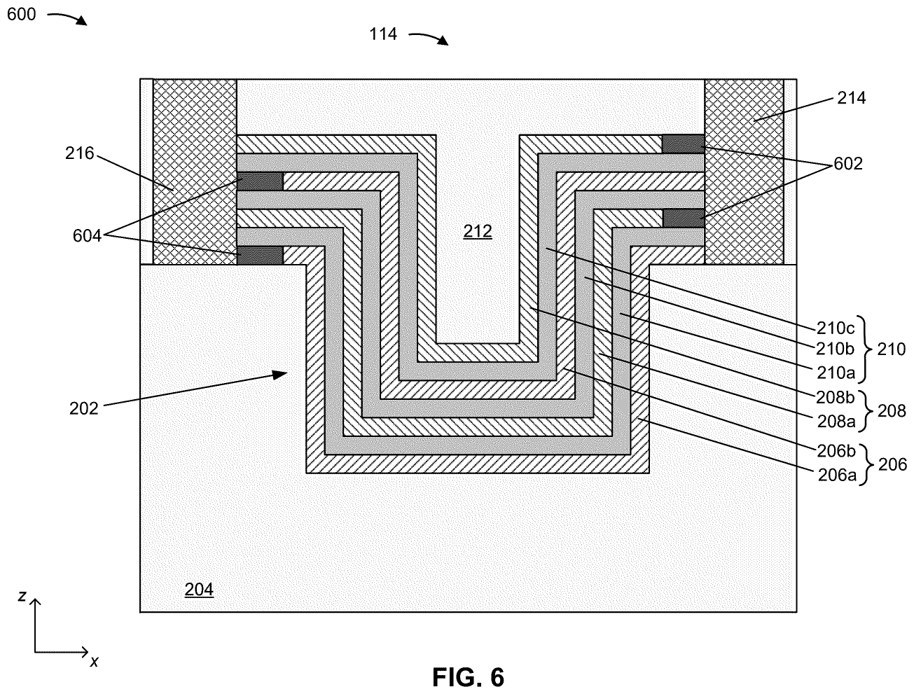

FIG. 6 is a diagram of an example capacitor structure 600 described herein. The capacitor structure 600 may include an example structural implementation of an overflow capacitor 114 of a pixel sensor 100 described herein. As shown in FIG. 6, the capacitor structure 600 includes a similar combination and arrangement of layers and/or structures 202-216 as the capacitor structure 200. However, in the capacitor structure 600, the airgaps 218 are filled in with insulator plugs 602, and the airgaps 220 are filled in with insulator plugs 604.

The insulator plugs 602 may be included between, and in physical contact with, the ends of the second electrode layers 208 and the sidewall of the first contact structure 214. Similarly, the insulator plugs 604 may be included between, and in physical contact with, the ends of the first electrode layers 206 and the sidewall of the second contact structure 216. The insulator plugs 602 may be formed to prevent material of the first contact structure 214 from being deposited on (and sticking to) the ends of the second electrode layers 208, and the insulator plugs 604 may be formed to prevent material of the second contact structure 216 from being deposited on (and sticking to) the ends of the first electrode layers 206.

In some implementations, the insulator plugs 602 and 604 include one or more dielectric materials. In some implementations, the insulator plugs 602 and 604 include one or more self-assembled monolayers (SAMs) formed of one or more organosilane compounds and/or one or more organosilane derivatives. For example, the insulator plugs 602 and 604 may each include one or more SAMs formed of an organosilane that includes a chloride or an alkoxide, among other examples.

As indicated above, FIG. 6 is provided as an example. Other examples may differ from what is described with regard to FIG. 6.

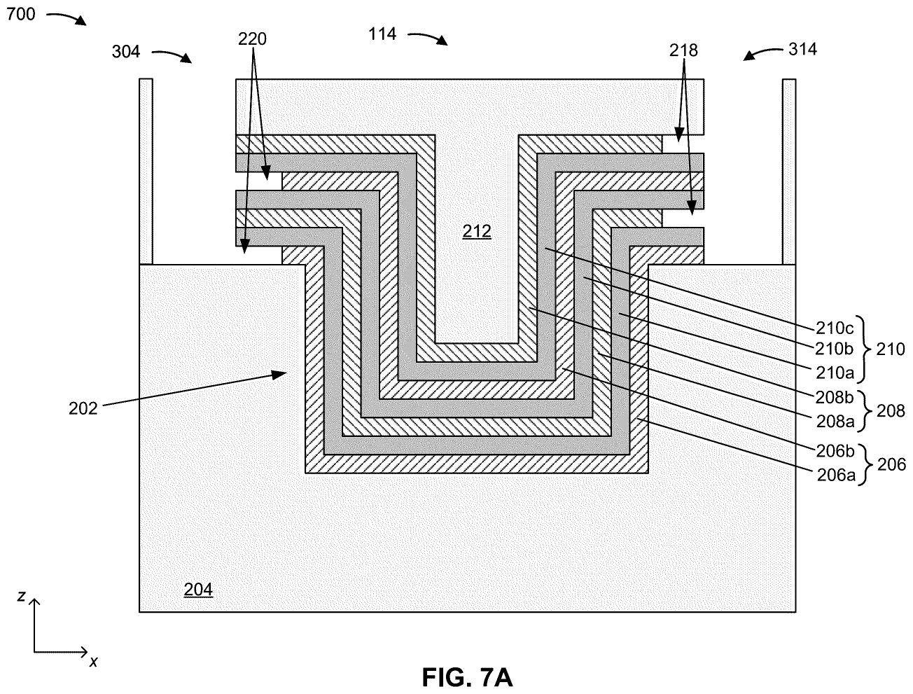

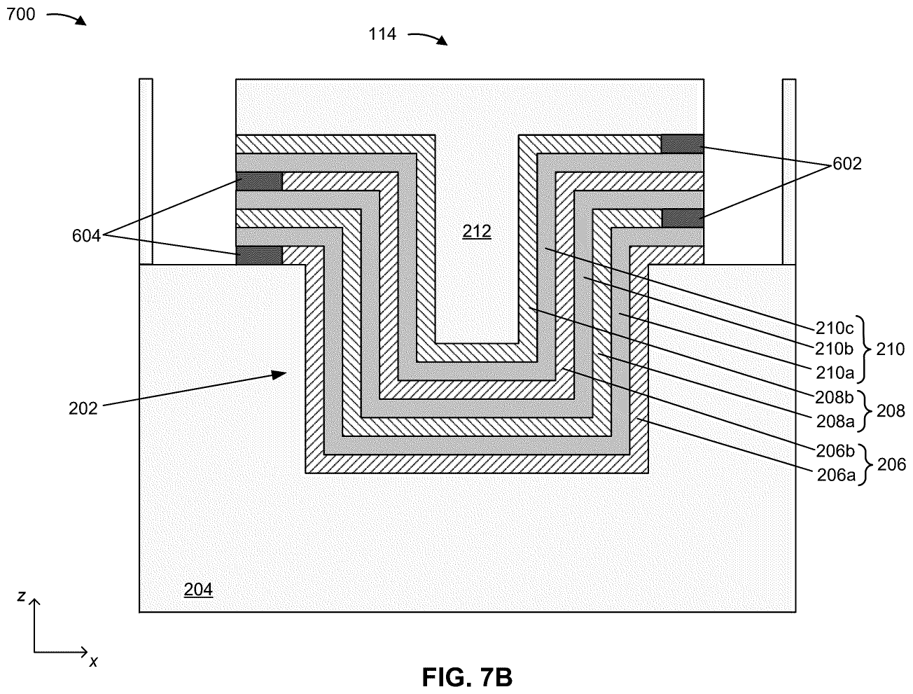

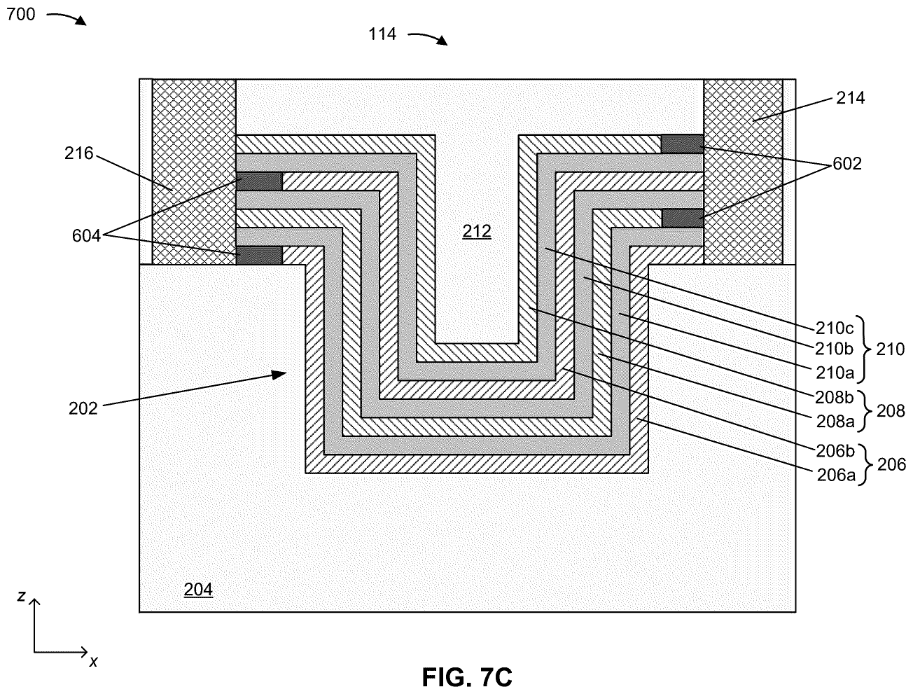

FIGS. 7A-7C are diagrams of an example implementation 700 of forming a capacitor structure 600 described herein. In some implementations, one or more of the semiconductor processing operations described in connection with FIGS. 7A-7C may be performed using one or more semiconductor processing tools, such as a deposition tool, an exposure tool, a developer tool, an etch tool, a planarization tool, a wafer/die transport tool, and/or another type of semiconductor processing tool.

As shown in FIG. 7A, similar processing operations as described in connection with FIGS. 3A-3K may be performed to form the trench 202, to form the MIM layer stack 302 including the first electrode layers 206, the second electrode layers 208, and the insulator layers 210, and to form the dielectric layer 212. Moreover, similar processing operations as described in connection with FIGS. 3A-3K may be performed to form the recesses 308 and 314, to etch the ends of the second electrode layers 208 to form the airgaps 218, and to etch the ends of the first electrode layers 206 to form the airgaps 220.

As shown in FIG. 7B, the insulator plugs 602 and 604 may be respectively formed in the recesses 314 and 308. A deposition tool may be used to deposit the insulator plugs 602 and 604 using a deposition technique such as CVD and/or ALD. In this way, the material of the insulator plugs 602 and 604 can be respectively deposited into the airgaps 218 and 220.

As shown in FIG. 7C, the first contact structure 214 is then deposited in the recess 314, and the second contact structure 216 is deposited in the recess 308. The first contact structure 214 and the second contact structure 216 may be deposited and planarized in a similar manner as described in connection with FIG. 3L. The insulator plugs 602 prevent material of the first contact structure 214 from being deposited on the ends of the second electrode layer 208, and the insulator plugs 604 prevent material of the second contact structure 216 from being deposited on the ends of the first electrode layer 206.

As indicated above, FIGS. 7A-7C are provided as an example. Other examples may differ from what is described with regard to FIGS. 7A-7C.

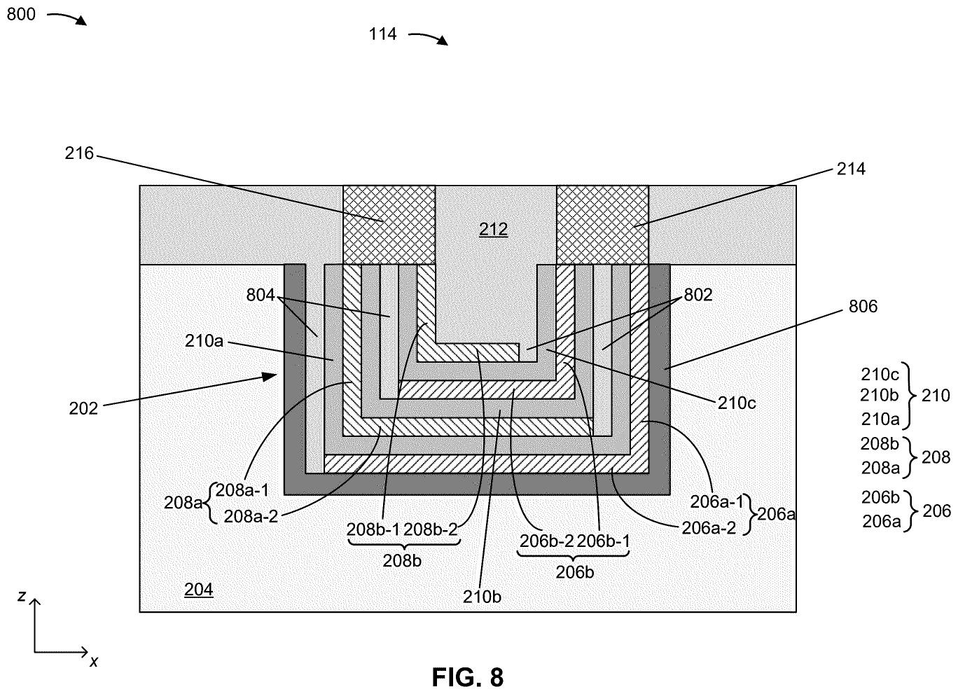

FIG. 8 is a diagram of an example capacitor structure 800 described herein. The capacitor structure 800 may include an example structural implementation of an overflow capacitor 114 of a pixel sensor 100 described herein.

As shown in FIG. 8, the capacitor structure 800 extends into a trench 202 in a dielectric layer 204, and includes first electrode layers 206, second electrode layers 208, insulator layers 210, a dielectric layer 212, a first contact structure 214, and a second contact structure 216, similar to the capacitor structures 200, 400, and 600.

First segments of the first electrode layers 206 may extend along a first sidewall of the trench 202, and second segments of the first electrode layers 206 may extend along the bottom surface of the trench 202. For example, segments 206a-1 and 206b-1, respectively, of the first electrode layers 206a and 206b may extend along the first sidewall of the trench 202, and segments 206a-2 and 206b-2, respectively, of the first electrode layers 206a and 206b may extend along the bottom surface of the trench 202.

First segments of the second electrode layers 208 may extend along a second sidewall of the trench 202 opposing the first sidewall, and second segments of the second electrode layers 208 may extend along the bottom surface of the trench 202. For example, segments 208a-1 and 208b-1, respectively, of the second electrode layers 208a and 208b may extend along the second sidewall of the trench 202, and segments 208a-2 and 208b-2, respectively, of the second electrode layers 208a and 208b may extend along the bottom surface of the trench 202. Thus, the second electrode layers 208 may have approximately L-shaped cross-sectional profiles, and the first electrode layers 206 may have approximately mirrored L-shaped cross-sectional profiles.

Ends of the segments 206a-1 and 206b-1, respectively, of the first electrode layers 206a and 206b may be approximately co-planar with the top of the trench 202, and the first contact structure 214 may be included on and in physical contact with the ends of the segments 206a-1 and 206b-1. Ends of the segments 208a-1 and 208b-1, respectively, of the second electrode layers 208a and 208b may be approximately co-planar with the top of the trench 202, and the second contact structure 216 may be included on and in physical contact with the ends of the segments 208a-1 and 208b-1. Including the first contact structure 214 above the trench 202 and directly on top of the ends of the first electrode layers 206, and including the second contact structure 216 directly above the trench 202 and directly on top of the ends of the second electrode layers 208, enables the lateral width of the capacitor structure 800 to be further reduced.

To electrically isolate the second electrode layers 208 from the first contact structure 214, dielectric spacers 802 are included between the first contact structure 214 and the ends of the segments 208a-2 and 208b-2, respectively, of the second electrode layers 208a and 208b. The dielectric spacers 802 may be formed as part of the process for forming the dielectric layer 212 and may include the same material composition as the dielectric layer 212. To electrically isolate the first electrode layers 206 from the second contact structure 216, dielectric spacers 804 are included between the second contact structure 216 and the ends of the segments 206a-2 and 206b-2, respectively, of the first electrode layers 206a and 206b. The dielectric spacers 804 may be formed as part of the process for forming the dielectric layer 212 and may include the same material composition as the dielectric layer 212.

The dielectric spacers 802 may be located between the first sidewall of the trench 202 and the ends of the segments 208a-2 and 208b-2, respectively, of the second electrode layers 208a and 208b. Moreover, a dielectric spacer 802 may be located laterally between the insulator layers 210a and 210b, and another dielectric spacer 802 may be located laterally between the insulator layer 210c and the dielectric layer 212.

The dielectric spacers 804 may be located between the second sidewall of the trench 202 and the ends of the segments 206a-2 and 206b-2, respectively, of the first electrode layers 206a and 206b. Moreover, a dielectric spacer 804 may be located laterally between the insulator layers 210b and 210c, and another dielectric spacer 804 may be located laterally between the insulator layer 210a and a dielectric etch stop layer 806 in the trench 202.

The dielectric etch stop layer 806 may include a silicon nitride (SiₓN_{y} such as Si₃N₄), an aluminum oxide (AlₓO_{y} such as Al₂O₃), and/or another suitable etch stop material that enables the first electrode layers 206 and the second electrode layers 208 to be etched to form recesses in which the dielectric spacers 802 and 804 can be formed, where the dielectric etch stop layer 806 protects the dielectric layer 204 from being etched in the trench 202. The dielectric etch stop layer 806 may be included on the sidewalls and bottom surface of the trench 202. The dielectric etch stop layer 806 may be included between the MIM layer stack of the capacitor structure 800 and the sidewalls and bottom surface of the trench 202. The ends of the dielectric etch stop layer 806 may be approximately co-planar with the top of the trench 202 because of a planarization operation that may be performed to planarize the MIM layer stack of the capacitor structure 800.

As indicated above, FIG. 8 is provided as an example. Other examples may differ from what is described with regard to FIG. 8.

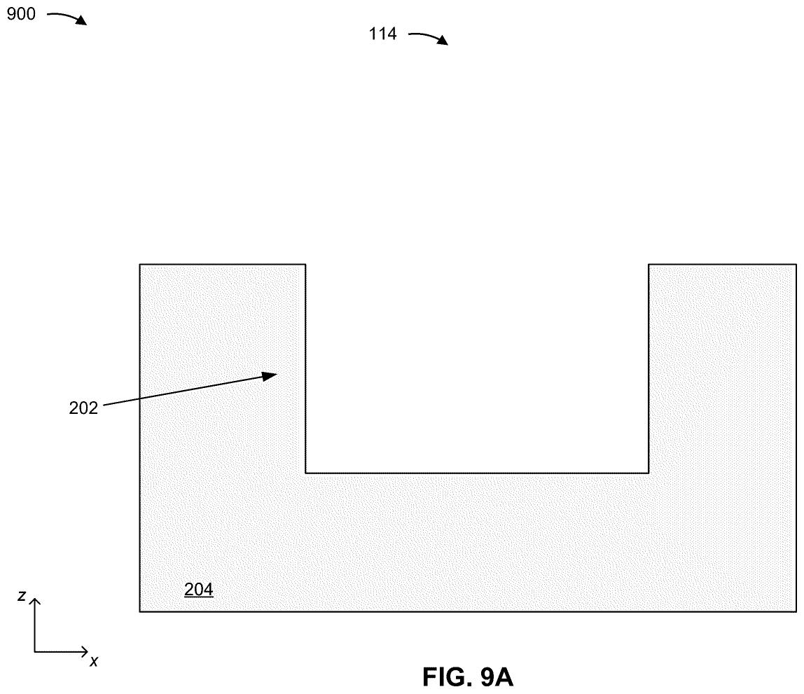

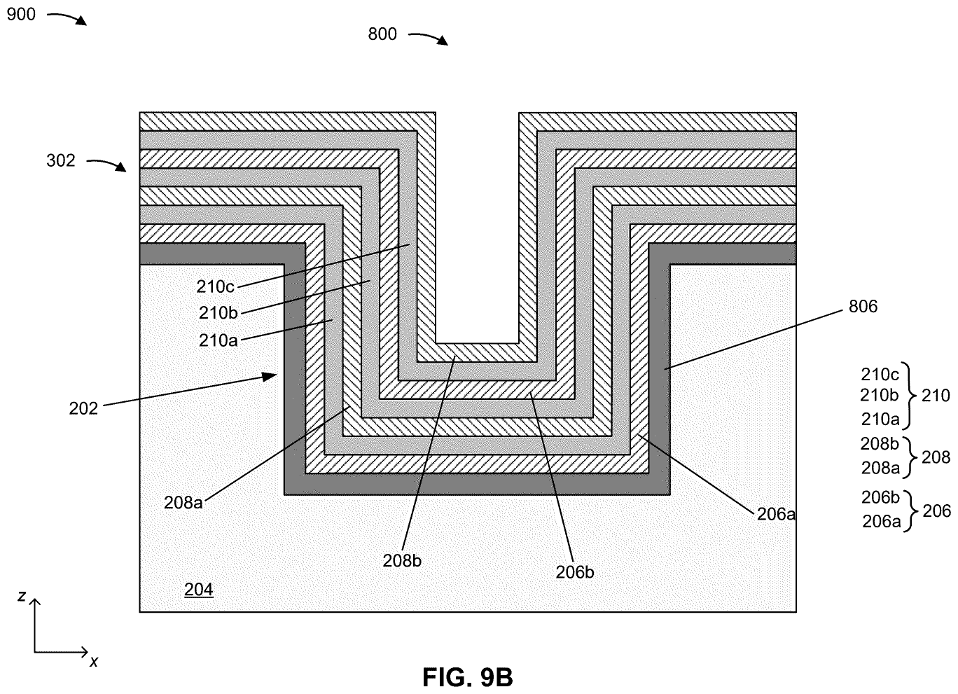

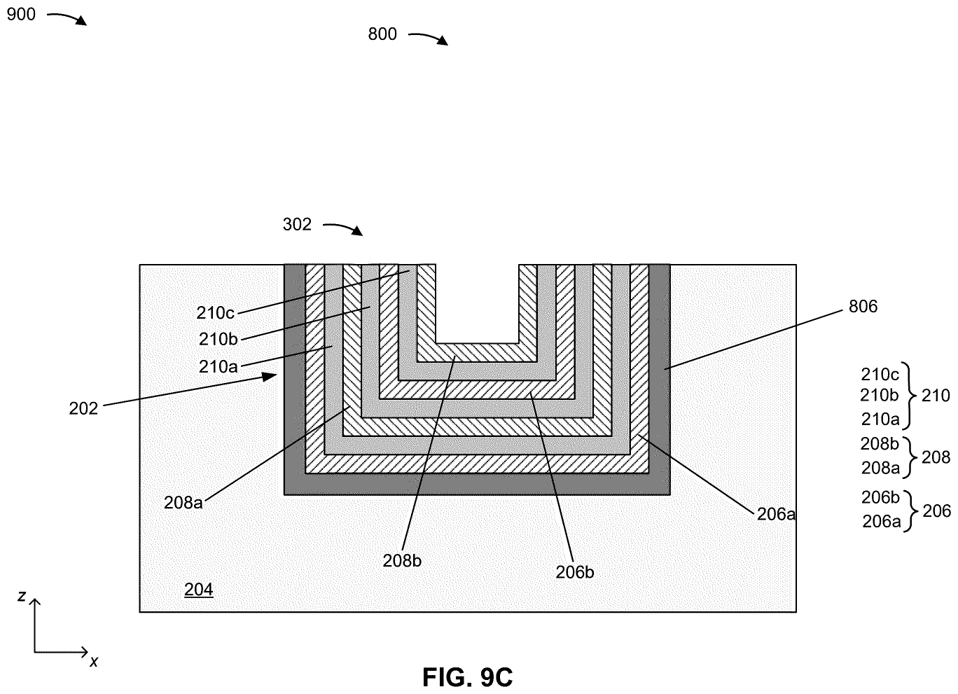

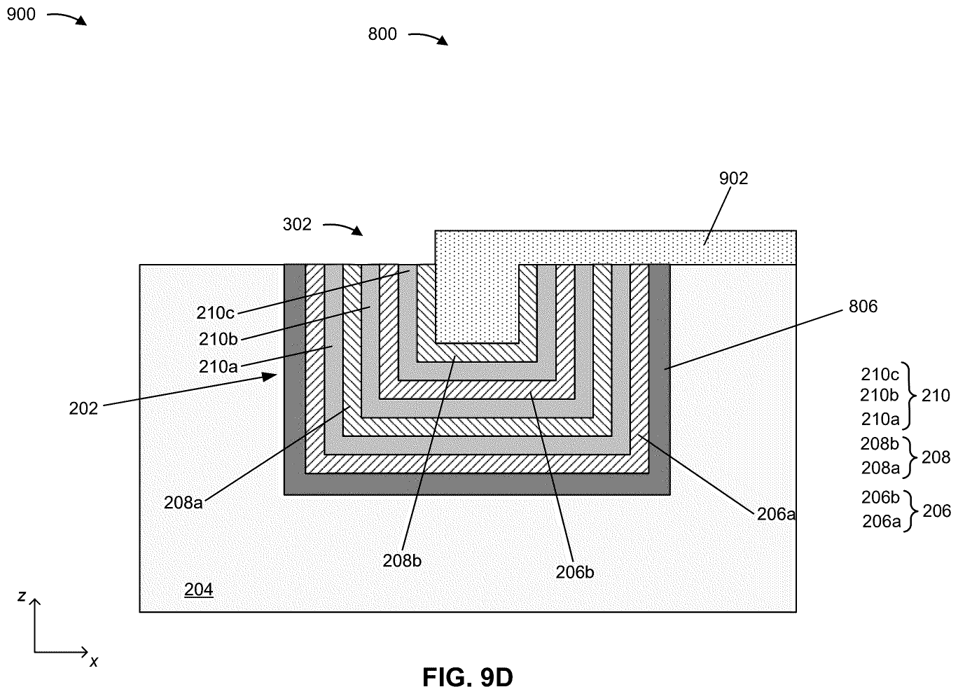

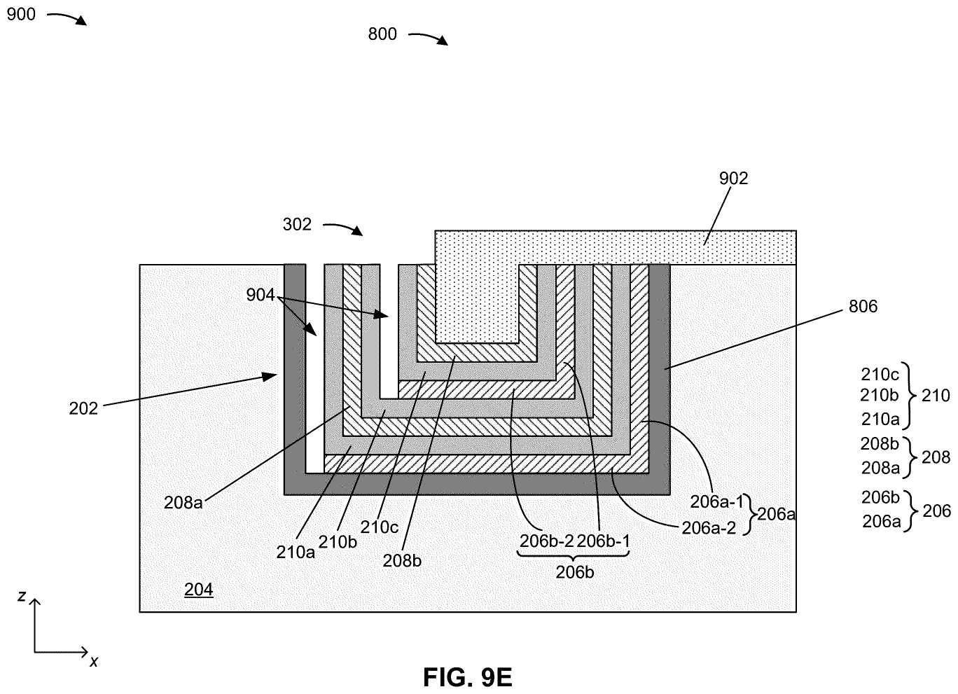

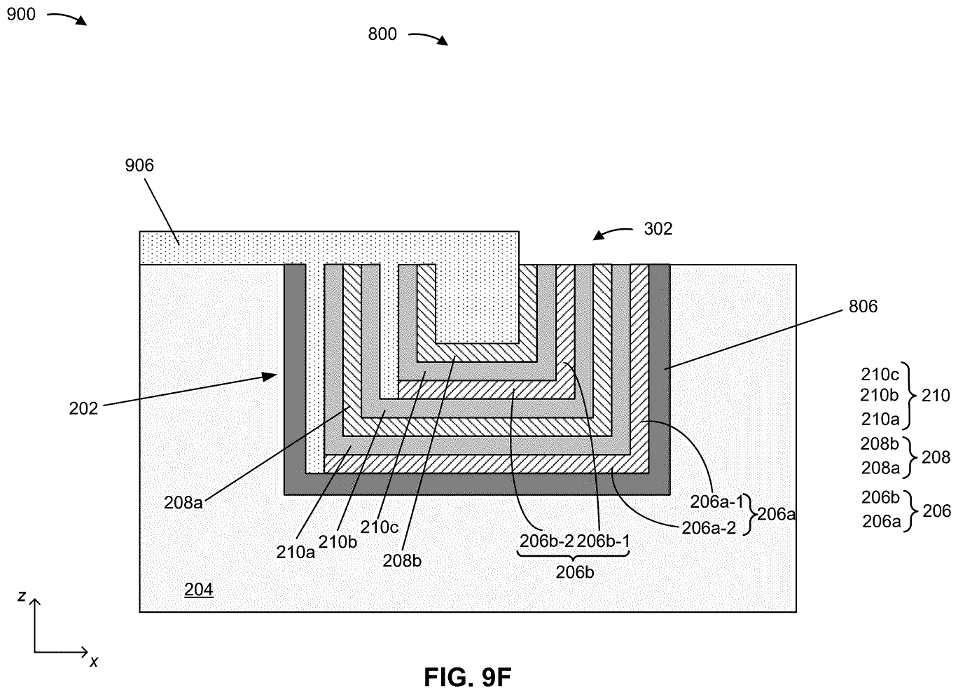

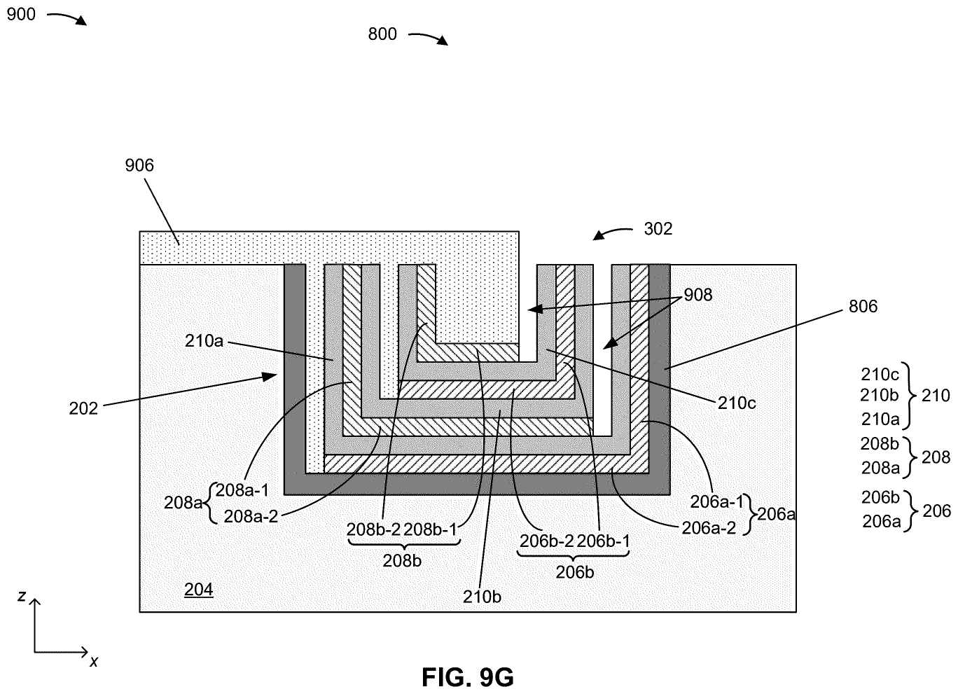

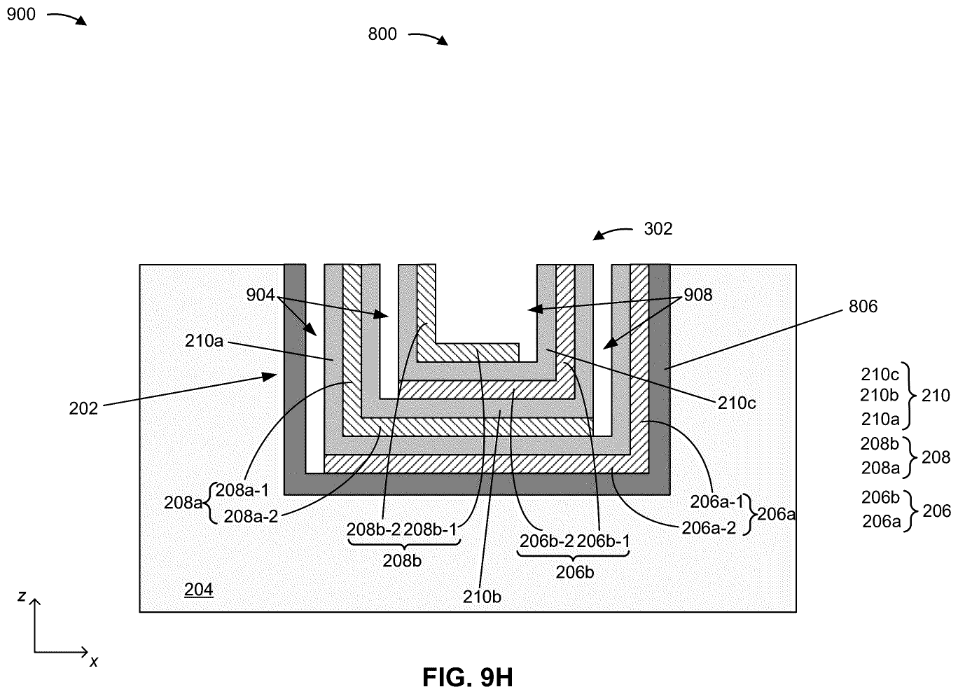

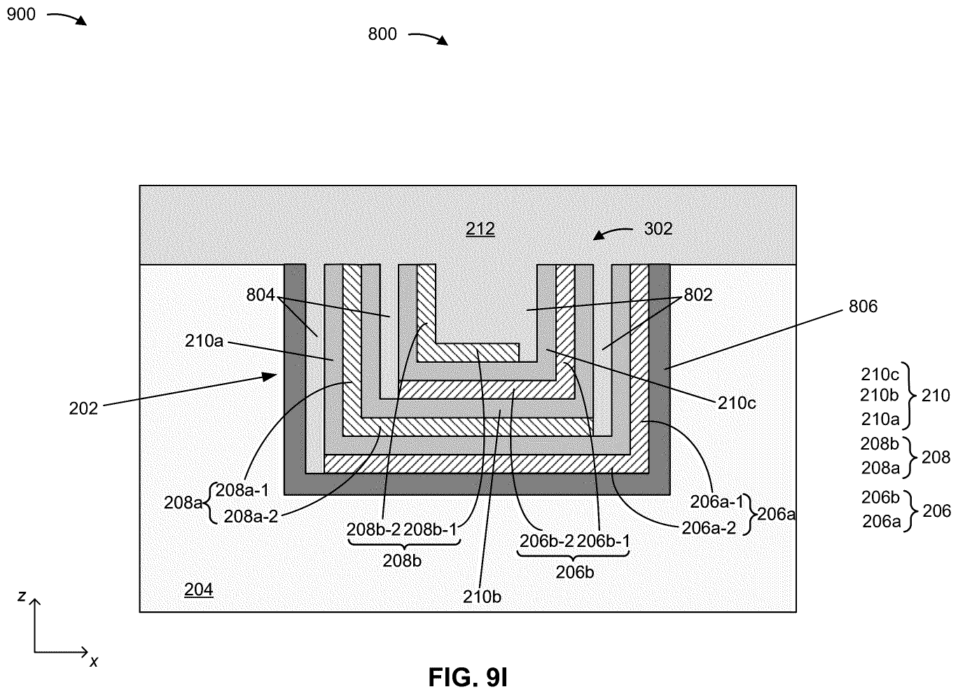

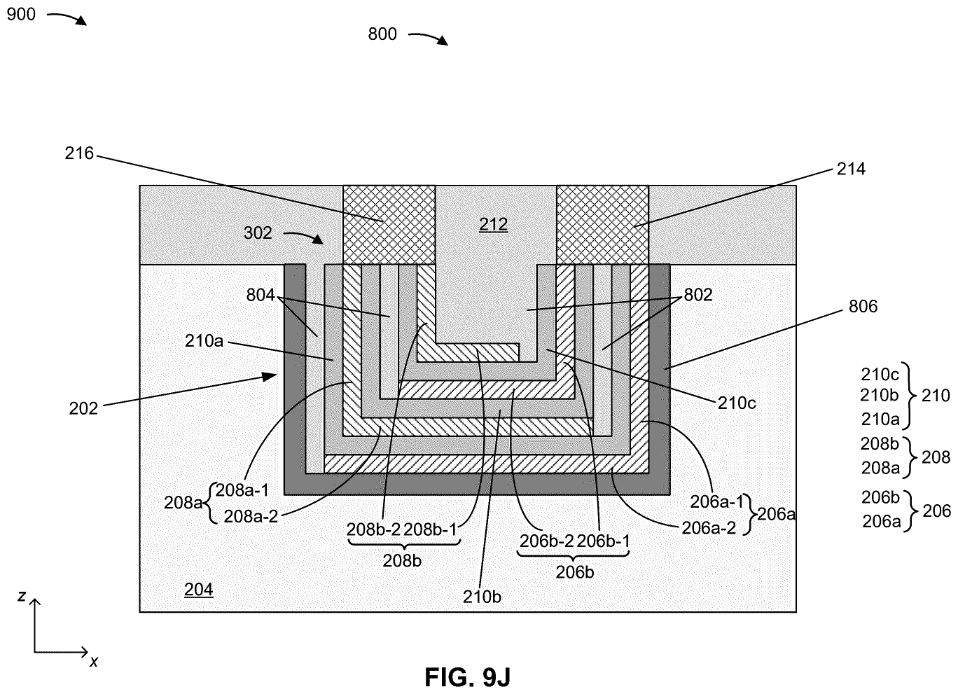

FIGS. 9A-9J are diagrams of an example implementation 900 of forming a capacitor structure 800 described herein. In some implementations, one or more of the semiconductor processing operations described in connection with FIGS. 9A-9J may be performed using one or more semiconductor processing tools, such as a deposition tool, an exposure tool, a developer tool, an etch tool, a planarization tool, a wafer/die transport tool, and/or another type of semiconductor processing tool.

As shown in FIG. 9A, the trench 202 may be formed in the dielectric layer 204. The trench 202 may be formed in a similar manner as described in connection with FIG. 3A.

As shown in FIG. 9B, the MIM layer stack 302 of the capacitor structure 800 is formed. The MIM layer stack 302 may be formed in a similar manner as described in connection with FIG. 3B. However, the dielectric etch stop layer 806 may first be deposited, and then the MIM layer stack 302 may be formed on the dielectric etch stop layer 806. In some implementations, a conformal deposition technique such as CVD and/or ALD may be used to deposit the dielectric etch stop layer 806. One or more deposition tools may be used to conformally deposit the dielectric etch stop layer 806 on the sidewalls and on the bottom surface of the trench 202.

As shown in FIG. 9C, a planarization operation may be performed to planarize the dielectric etch stop layer 806 and the MIM layer stack 302 of the capacitor structure 800. A planarization tool may be used to perform the planarization operation, which may include a CMP operation and/or another suitable planarization operation. The planarization operation results in removal of portions of the dielectric etch stop layer 806 and portions of the MIM layer stack 302 that extend above the trench 202 and along the top surface of the dielectric layer 204. Thus, the ends of the dielectric etch stop layer 806, the ends of the first electrode layers 206, the ends of the second electrode layers 208, and the end of the insulator layer 210 may be approximately co-planar with the top surface of the dielectric layer 204.

As shown in FIG. 9D, a masking layer 902 may be formed on the dielectric layer 204 and on the ends of the MIM layer stack 302. The masking layer 902 may be patterned such that the ends of the MIM layer stack 302 at a first side of the trench 202 are covered by the masking layer 902, and such that the ends of the MIM layer stack 302 at a second side of the trench 202 are exposed through the masking layer 902. In some implementations, the masking layer 902 includes a photoresist layer. In these implementations, a deposition tool may be used to form the masking layer 902 (e.g., using a spin-coating technique and/or another suitable deposition technique), an exposure tool may be used to expose the masking layer 902 to a radiation source to pattern the masking layer 902, and a developer tool may be used to develop and remove portions of the masking layer 902 to expose the pattern. In some implementations, the masking layer 902 includes a hard mask layer, and the pattern is formed in the masking layer 902 using a patterned photoresist layer.

As shown in FIG. 9E, an etch operation is performed to etch back the ends of the first electrode layers 206 that are exposed through the masking layer 902 to form recesses 904. The etch operation may include a wet chemical etch operation in which a wet etchant is used to selectively etch the ends of the first electrode layers 206 with minimal to no etching of the ends of the second electrode layers 208, the ends of the insulator layers 210, and the dielectric layer 204. Thus, the wet etchant may have a greater etch rate for the material of the first electrode layers 206 than the respective etch rates of the wet etchant for material of the second electrode layers 208, the material of the insulator layers 210, and the material of the dielectric layer 204.

As an example, the material of the first electrode layers 206 may include chromium (Cr), the material of the second electrode layers 208 may include molybdenum (Mo), and the material of the insulator layers 210 may include aluminum oxide (Al₂O₃). A chromium wet etchant that includes a mixture of perchloric acid (HClO₄) and ceric ammonium nitrate ((NH₄)₂[Ce(NO₃)₆]) may be used to etch the first electrode layers 206. The etch rate of the chromium wet etchant for the chromium of the first electrode layers 206 may be approximately 36 times to approximately 16,000 times greater than the etch rate of the chromium wet etchant for the molybdenum of the second electrode layers 208 and for the aluminum oxide of the insulator layers 210. However, other types of etchants, and other etch rate ranges, are within the scope of the present disclosure.

As another example, the material of the first electrode layers 206 may include gold (Au), the material of the second electrode layers 208 may include titanium nitride (TiN), and the material of the insulator layers 210 may include silicon nitride (Si₃N₄). A gold wet etchant that includes a mixture of nitric acid (HNO₃) and hydrochloric acid (HCl) may be used to etch the first electrode layers 206. In some implementations, the mixture of nitric acid and hydrochloric acid is diluted in water (H₂O). The etch rate of the gold wet etchant for the gold of the first electrode layers 206 may be at least approximately 1,300 times greater than the etch rate of the gold wet etchant for the titanium nitride of the second electrode layers 208 and for the silicon nitride of the insulator layers 210. However, other types of etchants, and other etch rate ranges, are within the scope of the present disclosure.

A photoresist removal tool may be used to remove the remaining portions of the masking layer 902 (e.g., using a chemical stripper, plasma ashing, and/or another technique) after the ends of the first electrode layers 206 are etched back.

As shown in FIG. 9F, the recesses 904 are filled in with another masking layer 906 that is also formed over the ends of the MIM layer stack 302 at the second side of the trench 202. The masking layer 906 may be deposited and patterned to expose the ends of the MIM layer stack 302 at the first side of the trench 202 through the masking layer 906.

As further shown in FIG. 9G, another etch operation is performed to etch back the ends of the second electrode layers 208 that are exposed through the masking layer 906 to form recesses 908. The etch operation may include a wet chemical etch operation in which a wet etchant is used to selectively etch the ends of the second electrode layers 208 with minimal to no etching of the ends of the first electrode layers 206, the ends of the insulator layers 210, and the dielectric layer 204. Thus, the wet etchant may have a greater etch rate for the material of the second electrode layers 208 than the respective etch rates of the wet etchant for material of the first electrode layers 206, the material of the insulator layers 210, and the material of the dielectric layer 204.

As an example, the material of the first electrode layers 206 may include chromium (Cr), the material of the second electrode layers 208 may include molybdenum (Mo), and the material of the insulator layers 210 may include aluminum oxide (Al₂O₃). A molybdenum wet etchant that includes nitric acid (HNO₃) may be used to etch the second electrode layers 208. In some implementations, the molybdenum wet etchant includes a mixture of nitric acid and ammonium fluoride (NH₄F) that is diluted in water (H₂O). The etch rate of the molybdenum wet etchant for the molybdenum of the second electrode layers 208 may be approximately 90 times to approximately 200 times greater than the etch rate of the molybdenum wet etchant for the chromium of the first electrode layers 206 and for the aluminum oxide of the insulator layers 210. However, other types of etchants, and other etch rate ranges, are within the scope of the present disclosure.

As another example, the material of the first electrode layers 206 may include gold (Au), the material of the second electrode layers 208 may include titanium nitride (TiN), and the material of the insulator layers 210 may include silicon nitride (Si₃N₄). A titanium nitride wet etchant that includes a hydrofluoric (HF) acid may be used to etch the second electrode layers 208. The etch rate of the titanium nitride wet etchant for the titanium nitride of the second electrode layers 208 may be at least approximately 180 times greater than the etch rate of the titanium nitride wet etchant for the gold of the first electrode layers 206 and for the silicon nitride of the insulator layers 210. However, other types of etchants, and other etch rate ranges, are within the scope of the present disclosure.

As shown in FIG. 9H, a photoresist removal tool may be used to remove the remaining portions of the masking layer 906 (e.g., using a chemical stripper, plasma ashing, and/or another technique) after the ends of the second electrode layers 208 are etched back into the trench 202. The removal of the masking layer 906 results in the recesses 904 at the second side of the trench 202 being exposed again.

As shown in FIG. 9I, the remaining area in the trench 202, along with the recesses 904 and 908, may be filled in with dielectric material to form the dielectric layer 212 and the dielectric spacers 802 and 804. The dielectric layer 212 may also be deposited over the ends of the MIM layer stack 302 and along the top surface of the dielectric layer 204. The dielectric spacers 802 may be formed in the recesses 908, and the dielectric spacers 804 may be formed in the recesses 904. A deposition tool may be used to deposit the material of the dielectric layer 212 and the dielectric spacers 802 and 804 using a PVD technique, an ALD technique, a CVD technique, an oxidation technique, and/or another suitable deposition technique. In some implementations, a planarization tool may be used to perform a planarization operation (e.g., a CMP operation) to planarize the dielectric layer 212 after the dielectric layer 212 is deposited.

As shown in FIG. 9J, the first contact structure 214 and the second contact structure 216 may be formed in the dielectric layer 212 above the trench 202. The first contact structure 214 may be formed directly on top of the ends of the first electrode layers 206 that extend to the top of the trench 202. The second contact structure 216 may be formed directly on top of the ends of the second electrode layers 208 that extend to the top of the trench 202.

A deposition tool may be used to deposit the first contact structure 214 and the second contact structure 216 in the recesses. A deposition tool may be used to deposit the first contact structure 214 and the second contact structure 216 using a CVD technique, a PVD technique, an ALD technique, an electroplating technique, and/or another suitable deposition technique. The first contact structure 214 and the second contact structure 216 may be deposited in one or more deposition operations. In some implementations, a seed layer is first deposited, and the first contact structure 214 and/or the second contact structure 216 is deposited on the seed layer. In some implementations, a planarization tool is used to perform a planarization operation (e.g., a CMP operation) to planarize the first contact structure 214 and the second contact structure 216 after the first contact structure 214 and the second contact structure 216 are deposited.

As indicated above, FIGS. 9A-9J are provided as an example. Other examples may differ from what is described with regard to FIGS. 9A-9J.

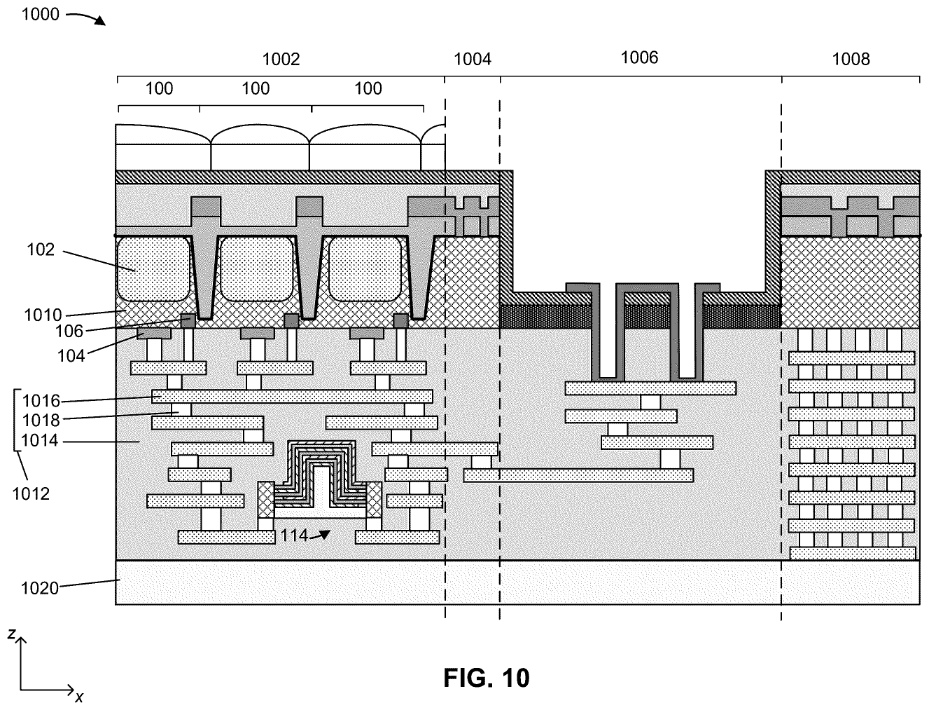

FIG. 10 is a diagram of an example semiconductor device 1000 described herein. The semiconductor device 1000 may include an example of a three-dimensional image sensor (e.g., a 3D complementary metal-oxide-semiconductor (CMOS) image sensor). The semiconductor device 1000 may be configured to be deployed in various implementations, such as digital cameras, video recorders, night-vision cameras, automotive sensors and cameras, and/or other types of light-sensing implementations.

As shown in FIG. 10, the semiconductor device 1000 may include a pixel sensor array 1002. The semiconductor device 1000 may further include a black level correction (BLC) region 1004, a bonding pad region 1006, and/or a seal ring region 1008, among other examples. The pixel sensor array 1002 may include a plurality of pixel sensors 100 arranged in an array. The pixel sensors 100 may be configured to sense incident light and convert photons of the incident light to a photocurrent. The pixel sensors 100 may be included in a device layer 1010 of the semiconductor device 1000. The pixel sensors 100 may each include one or more photodiodes 102 that are configured to generate a photocurrent based on photons of incident light. The pixel sensors 100 may further include a floating diffusion node 106 in the device layer 1010 that is configured to temporarily store the photocurrent generated by an associated pixel sensor 100, and may each include a transfer gate 104 that is configured to control the flow of photocurrent from a photodiode 102 to a floating diffusion node 106. The pixel sensors 100 may be formed by one or more semiconductor processing tools using various semiconductor processing techniques, such as photolithography, etching, deposition, CMP, and/or ion implantation, among other examples.

The BLC region 1004 includes a metal shielding layer over a portion of the device layer 1010 so that a baseline measurement of current in the device layer 1010 in the BLC region 1004 can be performed to determine the dark current (e.g., the current in the device layer 1010 that is generated from sources other than incident light such as heat) of the pixel sensor array 1002 so that the black level of the pixel sensor array 1002 can be adjusted to compensate for the dark current. The bonding pad region 1006 may include one or more conductive bonding pads (or e-pads) and/or metallization layers through which electrical connections between the semiconductor device 1000 and outside devices and/or external packaging may be established. The seal ring region 1008 may include an arrangement of metallization structures and interconnect structures to provide structural rigidity for the semiconductor device 1000 and to protect the semiconductor device 1000 from ingress of humidity and other contaminants.

As further shown in FIG. 10, the semiconductor device 1000 may include an interconnect layer 1012 below and/or under the device layer 1010. The interconnect layer 1012 may include a dielectric region 1014 that includes one or more dielectric layers (e.g., ILD layers, IMD dielectric layers, ESL layers) and an arrangement of metallization structures 1016 and interconnect structures 1018 in the dielectric region 1014. A passivation layer 1020 may be included under the interconnect layer 1012.

As further shown in FIG. 10, one or more overflow capacitors 114 may be included in the interconnect layer 1012. The overflow capacitor(s) 114 may be structurally implemented as one or more of the capacitor structures 200, 400, 600, and/or 800 illustrated and described herein. An overflow capacitor 114 may be electrically coupled to a floating diffusion node 106 of a pixel sensor 100 and may be configured to store overflow photocurrent from the floating diffusion node 106.

As indicated above, FIG. 10 is provided as an example. Other examples may differ from what is described with regard to FIG. 10.

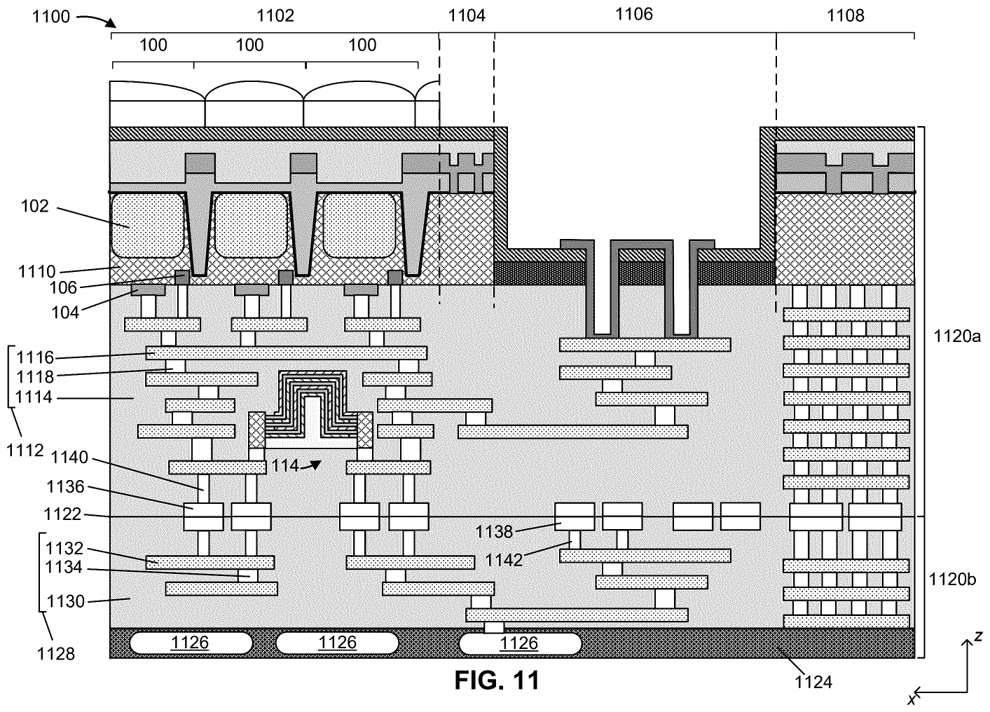

FIG. 11 is a diagram of an example semiconductor device 1100 described herein. The semiconductor device 1100 may include an example of a three-dimensional image sensor (e.g., a 3D CMOS image sensor). The semiconductor device 1100 may be configured to be deployed in various implementations, such as digital cameras, video recorders, night-vision cameras, automotive sensors and cameras, and/or other types of light-sensing implementations.

As shown in FIG. 11, the semiconductor device 1100 includes a similar combination of structures and/or layers as the semiconductor device 1000. For example, the semiconductor device 1100 may include elements 1102-1118, which are similar to the elements 1002-1018 of the semiconductor device 1000.

However, the semiconductor device 1100 includes a plurality of semiconductor dies, including a first semiconductor die 1120a and a second semiconductor die 1120b. The first semiconductor die 1120a and the second semiconductor die 1120b may be directly bonded together at a bonding interface 1122 such that the first semiconductor die 1120a and the second semiconductor die 1120b are stacked and vertically arranged in a z-direction in the semiconductor device 1100. The first semiconductor die 1120a may be referred to as an image sensor die and may include the pixel sensor array 1102 (including the pixel sensors 100), the BLC region 1104, and the bonding pad region 1106. The first semiconductor die 1120a may also include the photodiodes 102, the transfer gates 104, the floating diffusion nodes 106, the device layer 1110, and the interconnect layer 1112 (including the dielectric region 1114, the metallization structures 1116 and the interconnect structures 1118). In the example in FIG. 11, the overflow capacitor(s) 114 are included in the interconnect layer 1112 of the first semiconductor die 1120a. The seal ring region 1108 may extend through both the first semiconductor die 1120a and the second semiconductor die 1120b.

As further shown in FIG. 11, the second semiconductor die 1120b of the semiconductor device 1100 may include a device layer 1124, one or more integrated circuit devices 1126 included in the device layer 1124, and an interconnect layer 1128 above the device layer 1124. The interconnect layer 1128 may include a dielectric region 1130 that includes one or more dielectric layers (e.g., ILD layers, ESLs) and an arrangement of metallization structures 1132 and interconnect structures 1134 in the dielectric region 1130 of the interconnect layer 1128 of the second semiconductor die 1120b.

The first semiconductor die 1120a and the second semiconductor die 1120b may be bonded at the bonding interface 1122 by dielectric-to-dielectric bonds between the dielectric region 1114 of the first semiconductor die 1120a and the dielectric region 1130 of the second semiconductor die 1120b. Moreover, the first semiconductor die 1120a and the second semiconductor die 1120b may be bonded at the bonding interface 1122 by metal-to-metal bonds between bonding pads 1136 included in the interconnect layer 1112 of the first semiconductor die 1120a and bonding pads 1138 included in the interconnect layer 1128 of the second semiconductor die 1120b. The bonding pads 1136 may be electrically connected to the metallization structures 1116 and the interconnect structures 1118 in the interconnect layer 1112 by bonding vias 1140, and the bonding pads 1138 may be electrically connected to the metallization structures 1132 and the interconnect structures 1134 in the interconnect layer 1128 by bonding vias 1142.

As indicated above, FIG. 11 is provided as an example. Other examples may differ from what is described with regard to FIG. 11.

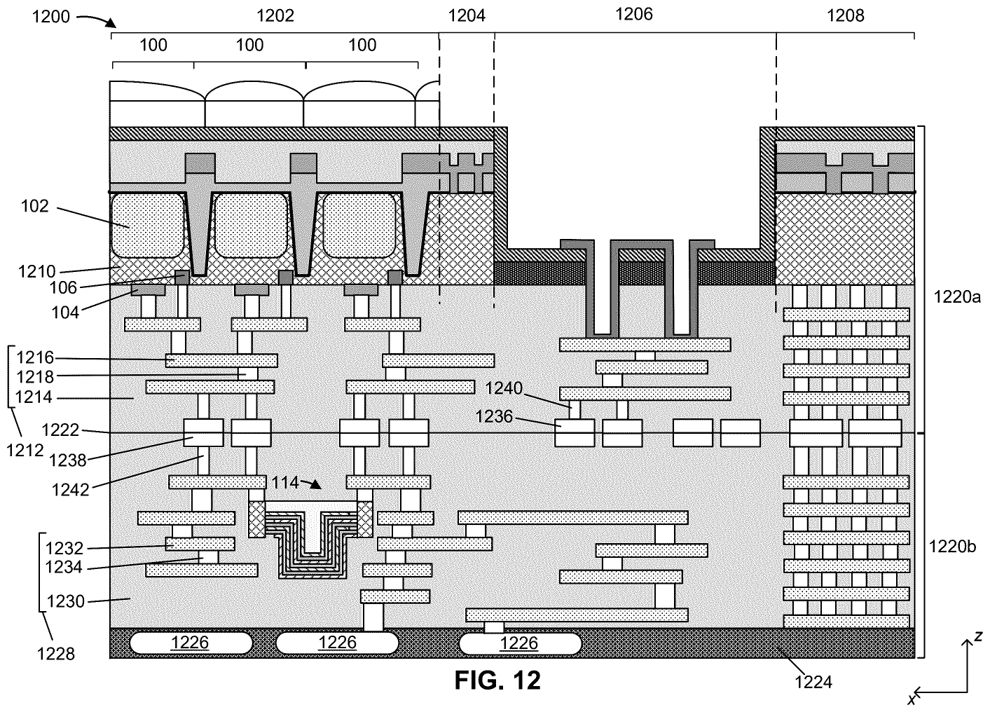

FIG. 12 is a diagram of an example semiconductor device 1200 described herein. The semiconductor device 1200 may include an example of a three-dimensional image sensor (e.g., a 3D CMOS image sensor). The semiconductor device 1200 may be configured to be deployed in various implementations, such as digital cameras, video recorders, night-vision cameras, automotive sensors and cameras, and/or other types of light-sensing implementations.

As shown in FIG. 12, the semiconductor device 1200 includes a similar combination of structures and/or layers as the semiconductor device 1100. For example, the semiconductor device 1200 may include elements 1202-1242, which are similar to the elements 1102-1142 of the semiconductor device 1100. The semiconductor device 1200 may also include pixel sensors 100, photodiodes 102, transfer gates 104, floating diffusion nodes 106, and one or more overflow capacitors 114.

However, in the semiconductor device 1200, the one or more overflow capacitors 114 are included in the second semiconductor die 1220b (e.g., an application-specific integrated circuit (ASIC) die) as opposed to (or in addition to) being included in the first semiconductor die 1220a (e.g., the sensor die). Including the one or more overflow capacitors 114 on the second semiconductor die 1220b as opposed to the first semiconductor die 1220a enables a greater amount of the area in the first semiconductor die 1220a to be used for the photodiodes 102 (which provides increased full well capacity for the photodiodes 102) and/or for control circuitry of the pixel sensors 100 (e.g., for the transfer gates 104, the reset gates 108, the overflow gates 112), which may increase the performance of the semiconductor device 1200.

As indicated above, FIG. 12 is provided as an example. Other examples may differ from what is described with regard to FIG. 12.

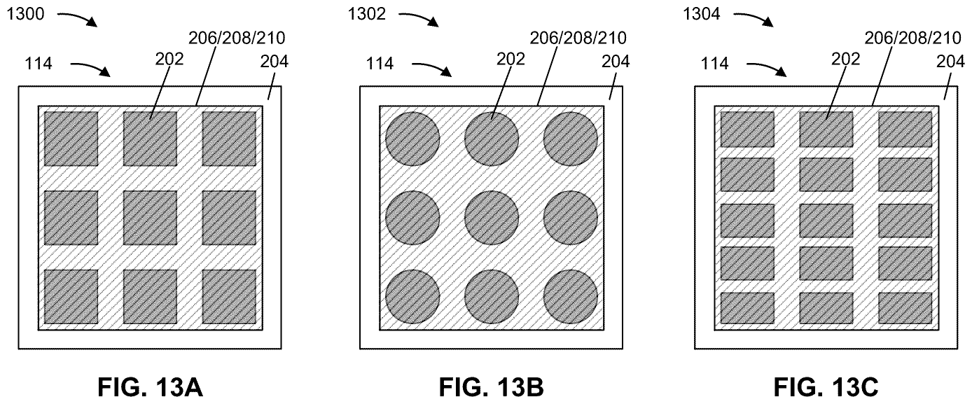

FIGS. 13A-13C are diagrams of example top view layouts for overflow capacitors 114 described herein. The overflow capacitors 114 may be implemented as one or more of the capacitor structures 200, 400, 600, and/or 800 described herein.

FIG. 13A illustrates an example top view layout 1300 in which an overflow capacitor 114 may include a plurality of approximately square-shaped trenches 202 that are arranged in a grid. Including a plurality of trenches 202 may further increase the capacitance of the overflow capacitor 114.

FIG. 13B illustrates an example top view layout 1302 in which an overflow capacitor 114 similarly includes a plurality of trenches 202. However, the trenches 202 in the top view layout 1302 include a plurality of approximately circle-shaped trenches 202 that are arranged in a grid.

FIG. 13C illustrates an example top view layout 1304 in which an overflow capacitor 114 similarly includes a plurality of trenches 202. However, the trenches 202 in the top view layout 1304 include a plurality of approximately rectangle-shaped trenches 202 that are arranged in a grid.

As indicated above, FIGS. 13A-13C are provided as examples. Other examples may differ from what is described with regard to FIGS. 13A-13C. The quantities, shapes, and arrangements of trenches 202 in the example top view layouts in FIGS. 13A-13C are examples, and other quantities, shapes, and arrangements are within the scope of the present disclosure.

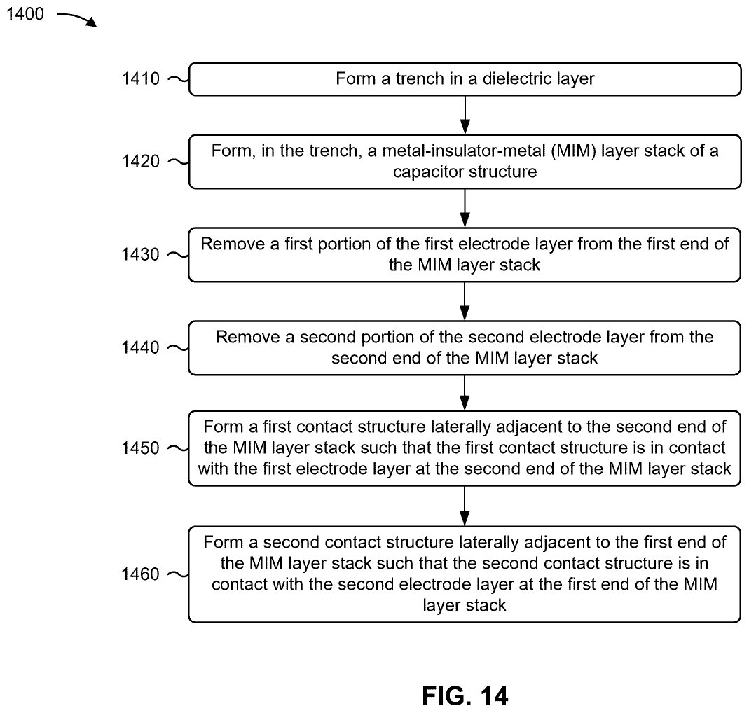

FIG. 14 is a flowchart of an example process 1400 associated with forming a capacitor structure described herein. In some implementations, one or more process blocks of FIG. 14 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 14, process 1400 may include forming a trench in a dielectric layer (block 1410). For example, one or more semiconductor processing tools may be used to form a trench 202 in a dielectric layer 204, as described herein.

As further shown in FIG. 14, process 1400 may include forming, in the trench, an MIM layer stack of a capacitor structure (block 1420). For example, one or more semiconductor processing tools may be used to form, in the trench 202, an MIM layer stack of a capacitor structure (e.g., a capacitor structure 200, 400, 600, and/or 800), as described herein. In some implementations, the MIM layer stack extends along sidewalls and a bottom surface of the trench 202. In some implementations, the MIM layer stack includes a repeating arrangement of a first electrode layer 206, an insulator layer 210 on the first electrode layer 206, and a second electrode layer 208 on the insulator layer 210. In some implementations, a first end of the MIM layer stack extends laterally outward from a first side of the trench 202 along a top surface of the dielectric layer 204. In some implementations, a second end of the MIM layer stack extends laterally outward from a second side of the trench 202 along the top surface of the dielectric layer 204.

As further shown in FIG. 14, process 1400 may include removing a first portion of the first electrode layer from the first end of the MIM layer stack (block 1430). For example, one or more semiconductor processing tools may be used to remove a first portion of the first electrode layer 206 from the first end of the MIM layer stack, as described herein.

As further shown in FIG. 14, process 1400 may include removing a second portion of the second electrode layer from the second end of the MIM layer stack (block 1440). For example, one or more semiconductor processing tools may be used to remove a second portion of the second electrode layer 208 from the second end of the MIM layer stack, as described herein.

As further shown in FIG. 14, process 1400 may include forming a first contact structure laterally adjacent to the second end of the MIM layer stack such that the first contact structure is in contact with the first electrode layer at the second end of the MIM layer stack (block 1450). For example, one or more semiconductor processing tools may be used to form a first contact structure 214 laterally adjacent to the second end of the MIM layer stack such that the first contact structure 214 is in contact with the first electrode layer 206 at the second end of the MIM layer stack, as described herein.

As further shown in FIG. 14, process 1400 may include forming a second contact structure (216) laterally adjacent to the first end of the MIM layer stack such that the second contact structure is in contact with the second electrode layer at the first end of the MIM layer stack (block 1460). For example, one or more semiconductor processing tools may be used to form a second contact structure 216 laterally adjacent to the first end of the MIM layer stack such that the second contact structure 216 is in contact with the second electrode layer 208 at the first end of the MIM layer stack, as described herein.

Process 1400 may include additional implementations, such as any single implementation or any combination of implementations described below and/or in connection with one or more other processes described elsewhere herein.

In a first implementation, the first contact structure 214 is laterally spaced apart from the second electrode layer 208 at the second end of the MIM layer stack, and the second contact structure 216 is laterally spaced apart from the first electrode layer 206 at the first end of the MIM layer stack.

In a second implementation, alone or in combination with the first implementation, removing the first portion of the first electrode layer 206 from the first end of the MIM layer stack includes etching the first electrode layer 206 to remove the first portion using an etchant, where a first etch rate of the etchant for the first electrode layer 206 is greater than a second etch rate of the etchant for the second electrode layer 208.

In a third implementation, alone or in combination with one or more of the first and second implementations, removing the second portion of the second electrode layer 208 from the second end of the MIM layer stack includes etching the second electrode layer 208 to remove the second portion using another etchant, where a first etch rate of the etchant for the second electrode layer 208 is greater than a second etch rate of the etchant for the first electrode layer 206.

In a fourth implementation, alone or in combination with one or more of the first through third implementations, the etchant includes perchloric acid (HClO₄) and ceric ammonium nitrate ((NH₄)₂[Ce(NO₃)₆]), and the other etchant includes nitric acid (HNO₃).

In a fifth implementation, alone or in combination with one or more of the first through fourth implementations, the etchant includes nitric acid (HNO₃) and hydrochloric acid (HCl), and the other etchant includes hydrofluoric acid (HF).

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, an image sensor device includes a capacitor structure that is configured to store charge associated with a photocurrent that is generated by a pixel sensor in a pixel sensor array of the image sensor device. The photocurrent may be transferred from the pixel sensor to the capacitor structure, which enables the pixel sensor to generate more charge for the photocurrent than if the photocurrent were wholly stored in the photodiode and/or floating diffusion node of the pixel sensor. Thus, the capacitor structure may increase the full well capacity of the pixel sensor, which may enable a higher range of brightness and/or contrast to be achieved in images and/or video generated by the pixel sensor array. The capacitor structure may include a metal-insulator-metal (MIM) layer stack in which bottom electrode layers and top electrode layers are arranged in an alternating manner and separated by insulator layers. The bottom contact structure for the bottom electrode layers and the top contact structure for the top electrode layers are formed laterally adjacent to opposing ends of the MIM layer stack. To electrically isolate the bottom electrode layers from the top contact structure, the ends of the bottom electrode layers facing the top contact structure are etched such that the ends of the bottom electrode layers are spaced apart from the top contact structure. Similarly, the ends of the top electrode layers facing the bottom contact structure are etched such that the ends of the top electrode layers are spaced apart from the bottom contact structure. This enables the bottom contact structure for the bottom electrode layers and the top contact structure for the top electrode layers to be formed laterally adjacent to the opposing ends of the MIM layer stack, which enables a more compact lateral footprint to be achieved for the capacitor structure.

As described in greater detail above, some implementations described herein provide a capacitor structure. The capacitor structure includes a first electrode layer that extends along sidewalls and a bottom surface of a trench, where a first end of the first electrode layer extends laterally outward from a first side of the trench. The capacitor structure includes a second electrode layer that extends along the sidewalls and the bottom surface of the trench, where a second end of the second electrode layer extends laterally outward from a second side of the trench. The capacitor structure includes an insulator layer between the first electrode layer and the second electrode layer. The capacitor structure includes a first contact structure in contact with the first end of the first electrode layer. The capacitor structure includes a second contact structure in contact with the second end of the second electrode layer.

As described in greater detail above, some implementations described herein provide a method. The method includes forming a trench in a dielectric layer. The method includes forming, in the trench, an MIM layer stack of a capacitor structure, where the MIM layer stack extends along sidewalls and a bottom surface of the trench, where the MIM layer stack comprises a repeating arrangement of a first electrode layer, an insulator layer on the first electrode layer, and a second electrode layer on the insulator layer, where a first end of the MIM layer stack extends laterally outward from a first side of the trench along a top surface of the dielectric layer, and where a second end of the MIM layer stack extends laterally outward from a second side of the trench along the top surface of the dielectric layer. The method includes removing a first portion of the first electrode layer from the first end of the MIM layer stack. The method includes removing a second portion of the second electrode layer from the second end of the MIM layer stack. The method includes forming a first contact structure laterally adjacent to the second end of the MIM layer stack such that the first contact structure is in contact with the first electrode layer at the second end of the MIM layer stack. The method includes forming a second contact structure laterally adjacent to the first end of the MIM layer stack such that the second contact structure is in contact with the second electrode layer at the first end of the MIM layer stack.

As described in greater detail above, some implementations described herein provide a capacitor structure. The capacitor structure includes a first electrode layer that extends along a first sidewall and a bottom surface of a trench. The capacitor structure includes a second electrode layer that extends along a second sidewall and the bottom surface of the trench. The capacitor structure includes an insulator layer between the first electrode layer and the second electrode layer. The capacitor structure includes a first contact structure on top of, and in contact with, a first end of the first electrode layer. The capacitor structure includes a second contact structure, on top of, and in contact with, a second end of the second electrode layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A capacitor structure, comprising:
a first electrode layer that extends along sidewalls and a bottom surface of a trench,
wherein a first end of the first electrode layer extends laterally outward from a first side of the trench;
a second electrode layer that extends along the sidewalls and the bottom surface of the trench,
wherein a second end of the second electrode layer extend laterally outward from a second side of the trench;
an insulator layer between the first electrode layer and the second electrode layer;
a first contact structure in contact with the first end of the first electrode layer; and
a second contact structure in contact with the second end of the second electrode layer.

2. The capacitor structure of claim 1, wherein the first side and the second side are opposing sides of the trench.

3. The capacitor structure of claim 1, wherein a third end of the first electrode layer extends laterally outward from the first side of the trench;
wherein a fourth end of the second electrode layer extends laterally outward from the first side of the trench;
wherein the third end of the first electrode layer is spaced apart from the second contact structure; and
wherein the fourth end of the second electrode layer is spaced apart from the first contact structure.

4. The capacitor structure of claim 3, further comprising:
a first airgap between the third end of the first electrode layer and the second contact structure; and
a second airgap between the fourth end of the second electrode layer and the first contact structure.

5. The capacitor structure of claim 4, wherein the first contact structure comprises:
a first barrier layer that extends into the second airgap from the first contact structure; and
wherein the second contact structure comprises:
a second barrier layer that extends into the first airgap from the second contact structure.

6. The capacitor structure of claim 3, further comprising:
a first insulator plug between the first electrode layer and the second contact structure; and
a second insulator plug between the second electrode layer and the first contact structure.

7. The capacitor structure of claim 6, wherein the first insulator plug is in contact with the first electrode layer at a first end of the first insulator plug; and
wherein the first insulator plug is in contact with the second contact structure at a second end of the first insulator plug opposing the first end.

8. A method, comprising:
forming a trench in a dielectric layer;
forming, in the trench, a metal-insulator-metal (MIM) layer stack of a capacitor structure,
wherein the MIM layer stack extends along sidewalls and a bottom surface of the trench,
wherein the MIM layer stack comprises a repeating arrangement of a first electrode layer, an insulator layer on the first electrode layer, and a second electrode layer on the insulator layer,
wherein a first end of the MIM layer stack extends laterally outward from a first side of the trench along a top surface of the dielectric layer, and
wherein a second end of the MIM layer stack extends laterally outward from a second side of the trench along the top surface of the dielectric layer;
removing a first portion of the first electrode layer from the first end of the MIM layer stack;
removing a second portion of the second electrode layer from the second end of the MIM layer stack;
forming a first contact structure laterally adjacent to the second end of the MIM layer stack such that the first contact structure is in contact with the first electrode layer at the second end of the MIM layer stack; and
forming a second contact structure laterally adjacent to the first end of the MIM layer stack such that the second contact structure is in contact with the second electrode layer at the first end of the MIM layer stack.

9. The method of claim 8, wherein the first contact structure is laterally spaced apart from the second electrode layer at the second end of the MIM layer stack; and
wherein the second contact structure is laterally spaced apart from the first electrode layer at the first end of the MIM layer stack.

10. The method of claim 8, wherein removing the first portion of the first electrode layer from the first end of the MIM layer stack comprises:
etching the first electrode layer to remove the first portion using an etchant,
wherein a first etch rate of the etchant for the first electrode layer is greater than a second etch rate of the etchant for the second electrode layer.

11. The method of claim 10, wherein removing the second portion of the second electrode layer from the second end of the MIM layer stack comprises:
etching the second electrode layer to remove the second portion using another etchant,
wherein a third etch rate of the other etchant for the second electrode layer is greater than a fourth etch rate of the etchant for the first electrode layer.

12. The method of claim 11, wherein the etchant includes perchloric acid (HClO₄) and ceric ammonium nitrate ((NH₄)₂[Ce(NO₃)₆]); and
wherein the other etchant includes nitric acid (HNO₃).

13. The method of claim 11, wherein the etchant includes nitric acid (HNO₃) and hydrochloric acid (HCl); and
wherein the other etchant includes hydrofluoric acid (HF).

14. A capacitor structure, comprising:
a first electrode layer that extends along a first sidewall and a bottom surface of a trench;
a second electrode layer that extends along a second sidewall and the bottom surface of the trench;
an insulator layer between the first electrode layer and the second electrode layer;
a first contact structure on top of, and in contact with, a first end of the first electrode layer; and
a second contact structure, on top of, and in contact with, a second end of the second electrode layer.

15. The capacitor structure of claim 14, wherein the first sidewall and the second sidewall are opposing sidewalls of the trench.

16. The capacitor structure of claim 14, further comprising:
a first dielectric spacer between a third end of the first electrode layer and the second sidewall of the trench; and
a second dielectric spacer between a fourth end of the second electrode layer and the first sidewall of the trench.

17. The capacitor structure of claim 16, wherein first dielectric spacer is located laterally between the first electrode layer and the second electrode layer.

18. The capacitor structure of claim 17, further comprising:
a first insulator layer located laterally between the second dielectric spacer and the first electrode layer; and
a second insulator layer located laterally between the first dielectric spacer and the second electrode layer.

19. The capacitor structure of claim 14, wherein the first end of the first electrode layer and the second end of the second electrode layer are approximately co-planar with a top of the trench; and
wherein the first contact structure and the second contact structure are located over the trench.

20. The capacitor structure of claim 14, further comprising:
a dielectric etch stop layer on the first sidewall, the second sidewall, and the bottom surface of the trench,
wherein the dielectric etch stop layer is located between the first electrode layer and the first sidewall, the second sidewall, and the bottom surface of the trench, and
wherein the dielectric etch stop layer is located between the second electrode layer and the first sidewall, the second sidewall, and the bottom surface of the trench.
